(19) United States
(12) Patent Application Publication
(10) Pub. No.: US 2026/0360253 A1
(43) Pub. Date: Nov. 12, 2026

(54) VEHICLE CONFIGURATION DETERMINATION FOR VEHICLE NAVIGATION

(71) Applicant: International Business Machines Corporation, Armonk, NY (US)

(72) Inventors: Michael Boone, Lutz, FL (US); Tiberiu Suto, Franklin, NY (US); Sarbajit Kumar Rakshit, Kolkata (IN); Carolina Garcia Delgado, Zapopan (MX)

(21) Appl. No.: 19/201,358

(22) Filed: May 7, 2025

(51) Int. Cl. G08G 1/0967; B60W 50/00; G01C 21/00; G06F 30/15

(52) U.S. Cl. CPC G08G 1/096708; B60W 50/00; G01C 21/3815; G01C 21/3841; G06F 30/15; G08G 1/096766; B60W 2050/0028; B60W 2552/10; B60W 2552/50; B60W 2554/4042; B60W 2555/20; B60W 2555/60; B60W 2556/40; B60W 2556/45

(57) ABSTRACT

Vehicle configuration determination for vehicle navigation is provided and includes receiving vehicle data associated with a set of vehicles present on a road segment. Infrastructure connectivity data associated with one or more infrastructures present on the road segment is received. Map data associated with the road segment is received. A machine learning (ML) model is applied to the vehicle data, the infrastructure connectivity data, and the map data. A set of vehicle configurations associated with the set of vehicles is determined based on an application of the ML model. A vehicle configuration from the set of vehicle configurations is selected based on one or more criteria. At least a first vehicle of the set of vehicles is controlled based on the selected vehicle configuration.

### BACKGROUND

The disclosure relates to vehicle navigation and more particularly, to a vehicle sensor utilized for navigation of the vehicle.

Autonomous vehicles, often called self-driving cars, are designed to drive the vehicle without human intervention. Autonomous vehicles utilize artificial intelligence (AI), machine learning (ML), and various sensors such as ultrasonic sensors, cameras, Radio Detection And Ranging (Radar), Light Detection and Ranging (lidar), GPS, inertial measurement units (IMUs), sonar, and odometers to analyze the surroundings and make decisions on the road.

Spatial mapping sensors such as the Lidar, are one of the key technologies that is being utilized by autonomous vehicles. Lidar sensors emit out laser beams to measure distances to objects around the vehicle, creating detailed 3D maps of the environment in which the autonomous vehicles are navigating. However, the autonomous vehicles integrate spatial data of the environment of a road segment from the various sensors (e.g., cameras, Radar, Lidar, GPS) to accurately identify and classify various objects such as vehicles present on the road segment, pedestrians, and obstacles. The integration of the data from the various sensors is vital for ensuring safe and efficient navigation of the autonomous vehicles that allows the autonomous vehicles to operate effectively in complex and dynamic environments.

### SUMMARY

In various embodiments of the disclosure, a computer-implemented method for vehicle configuration determination for vehicle navigation is described. The computer-implemented method includes receiving, by a computer, vehicle data associated with a set of vehicles present on a road segment. The vehicle data includes a speed of each vehicle of the set of vehicles, and a geographical location of each vehicle of the set of vehicles. The computer-implemented method further includes receiving, by the computer, infrastructure connectivity data associated with one or more infrastructures present on the road segment. The infrastructure connectivity data includes a geographical location of each infrastructure of the one or more infrastructures. Each infrastructure of the one or more infrastructures includes a first spatial mapping sensor. The computer-implemented method further includes receiving, by the computer, map data associated with the road segment. The computer-implemented method further includes applying, by the computer, a machine learning (ML) model to the vehicle data, the infrastructure connectivity data, and the map data. The computer-implemented method further includes determining, by the computer, a set of vehicle configurations associated with the set of vehicles based on an application of the ML model. Each vehicle configuration of the set of vehicle configurations indicates an arrangement of the set of vehicles on the road segment. The computer-implemented method further includes selecting, by the computer, a vehicle configuration from the set of vehicle configurations based on one or more criteria. The one or more criteria include one of a power consumption by a second spatial mapping sensor of each vehicle of the set of vehicles, a driving range of each vehicle of the set of vehicles, or a travel route of each vehicle of the set of vehicles. The computer-implemented method further includes controlling, by the computer, at least a first vehicle of the set of vehicles based on the selected vehicle configuration.

In various embodiments of the disclosure, a computer system for vehicle configuration determination for vehicle navigation is described. The computer system includes a processor set, one or more computer-readable storage media, and program instructions stored on the one or more computer-readable storage media. The program instructions are executable by the processor set and cause the processor set to receive vehicle data associated with a set of vehicles present on a road segment. The vehicle data includes a speed of each vehicle of the set of vehicles, and a geographical location of each vehicle of the set of vehicles. The program instructions further cause the processor set to receive infrastructure connectivity data associated with one or more infrastructures present on the road segment. The infrastructure connectivity data includes a geographical location of each infrastructure of the one or more infrastructures. Each infrastructure of the one or more infrastructures includes a first spatial mapping sensor. The program instructions further cause the processor set to receive map data associated with the road segment. The program instructions further cause the processor set to apply a machine learning (ML) model to the vehicle data, the infrastructure connectivity data, and the map data. The program instructions further cause the processor set to determine a set of vehicle configurations associated with the set of vehicles based on an application of the ML model. Each vehicle configuration of the set of vehicle configurations indicates an arrangement of the set of vehicles on the road segment. The program instructions further cause the processor set to select a vehicle configuration from the set of vehicle configurations based on one or more criteria. The one or more criteria include one of power consumption by a second spatial mapping sensor of each vehicle of the set of vehicles, a driving range of each vehicle of the set of vehicles, or a travel route of each vehicle of the set of vehicles. The program instructions further cause the processor set to obtain a first set of power values based on the selected vehicle configuration. The program instructions further cause the processor set to control a supply of power to a set of sensors of at least a first vehicle of the set of vehicles based on the obtained first set of power values. The set of sensors of at least the first vehicle includes the second spatial mapping sensor.

In various embodiments of the disclosure, a computer-program product for vehicle configuration determination for vehicle navigation is described.

Additional technical features and benefits are realized through the techniques of the disclosure. Embodiments and aspects of the disclosure are described in detail herein and are considered a part of the claimed subject matter. For a better understanding, refer to the detailed description and the drawings.

### BRIEF DESCRIPTION OF THE DRAWINGS

The following description will provide details of preferred embodiments with reference to the following figures wherein:

FIG. 1 is a diagram that illustrates a computing environment for vehicle configuration determination for vehicle navigation, in accordance with an embodiment of the disclosure;

FIG. 2 is a diagram that illustrates an environment for vehicle configuration determination for vehicle navigation, in accordance with an embodiment of the disclosure;

FIG. 3 is a diagram that illustrates a first set of exemplary operations for vehicle configuration determination for vehicle navigation, in accordance with an embodiment of the disclosure;

FIG. 4 is a diagram that illustrates exemplary operations for simulation of the set of vehicle configurations, in accordance with an embodiment of the disclosure;

FIG. 5 is a diagram that illustrates exemplary operations for generation of map based on geographical area, in accordance with an embodiment of the disclosure;

FIGS. 6A and 6B are diagrams that collectively illustrate an exemplary scenario for vehicle configuration determination for vehicle navigation, in accordance with an embodiment of the disclosure;

FIG. 7 is a diagram that illustrates an exemplary scenario for generation of a map based on geographical area, in accordance with an embodiment of the disclosure;

FIG. 8 is a diagram that illustrates a flowchart of a first exemplary method for vehicle configuration determination for vehicle navigation, in accordance with an embodiment of the disclosure; and

FIG. 9 is a diagram that illustrates a flowchart of a second exemplary method for vehicle configuration determination for vehicle navigation, in accordance with an embodiment of the disclosure.

### DETAILED DESCRIPTION

Autonomous vehicles, often called self-driving cars, are designed to drive the vehicle without human intervention. Autonomous vehicles utilize artificial intelligence (AI), machine learning (ML), and various sensors such as ultrasonic sensors to analyze the surroundings and make decisions on the road. Autonomous vehicles aim to make driving safer, reduce traffic jams, and provide better mobility options for people who may not be able to drive. Autonomous vehicles aim to improve road safety by focusing on reducing errors on the road while driving the vehicle. Human drivers can make mistakes, get distracted, or feel tired, which can lead to accidents. In contrast, self-driving cars are designed to use advanced technology to interpret data from the environment, allowing the self-driving cars to react to changing driving conditions in real-time.

Spatial mapping sensors such as the Lidar, are one of the key technologies that is being utilized by autonomous vehicles. Lidar sensors emit out laser beams to measure distances to objects around the vehicle, creating detailed 3D maps of the environment in which the autonomous vehicles are navigating. However, the autonomous vehicles integrate spatial data of the environment of a road segment from the various sensors (e.g., cameras, Radar, Lidar, GPS) to accurately identify and classify various objects such as vehicles present on the road segment, pedestrians, and obstacles. The integration of the data from the various sensors is vital for ensuring safe and efficient navigation of the autonomous vehicles that allows the autonomous vehicles to operate effectively in complex and dynamic environments.

Spatial mapping sensors consume high power to operate and assist vehicle navigation. A spatial mapping sensor is a device that measures distances and captures spatial data to create accurate three-dimensional representations of the environment of the road segment. The spatial mapping sensor (e.g., the Lidar) utilizes laser pulses to measure distances and generate detailed three-dimensional maps of the environment present in the proximity of the vehicle. The process of emitting and detecting the laser signals utilizes significant power, particularly in real-time applications such as autonomous vehicles. The power supply to the spatial mapping sensor is primarily drawn from the battery of the vehicle. High power consumption by the spatial mapping sensor leads to rapid draining of the battery further leading to a decrease in a range of the vehicle. The range of the vehicle corresponds to an estimated distance that can be covered by the vehicle based on available power in the battery of the vehicle. Since the spatial mapping sensor draws power from the vehicle's battery, the energy vital to operate the spatial mapping sensor reduces the overall energy available for navigation of the vehicle. Therefore, the vehicle's range is decreased, leading to challenges in scheduling vehicle recharge and vehicle navigation.

In one aspect, larger battery systems or more advanced battery systems can be utilized in the vehicle to assist the supply of power to the vehicle and to overcome the challenges associated with a decrease in the range of the vehicle. By utilizing the advanced battery systems, the energy capacity available for both vehicle navigation and operation of the spatial mapping sensor can be improved, thereby improving the overall performance of the vehicle. However, the utilization of advanced battery systems or larger battery systems increases the complexity of the design and engineering of the vehicle. Furthermore, the increase in complexity leads to higher manufacturing costs and additional maintenance costs, thereby leading to an increase in the overall operating cost of utilizing the spatial mapping sensor for vehicle navigation.

The decrease in the available range of the vehicle due to high power consumption by the spatial mapping sensor of the vehicle leads to range anxiety for the owner of the vehicle. A spatial mapping sensor is a device that measures distances and captures spatial data to create accurate three-dimensional representations of the environment of the road segment. Due to the randomized distribution of vehicles on the road segment, the spatial mapping sensor of the vehicle consumes high power to capture the arrangement of a set of vehicles present on the road segment which decreases the available range of the vehicle. The randomized distribution of the set of vehicles on the road segment poses a challenge to navigate the vehicle in real-time traffic conditions (e.g., changing the lane in which the vehicle is traveling) which may further increase the power consumption by the spatial mapping sensor of the vehicle. The disclosed system utilizes vehicle-to-vehicle (V2V) communication to enhance traffic awareness. V2V communication allows vehicles to exchange vehicle information such as vehicle location, vehicle speed, and vehicle lane movement. The exchange of the vehicle information among the set of vehicles reduces the power consumption by the spatial mapping sensor of each vehicle of the set of vehicles as the spatial data is received by each vehicle of the set of vehicles via the V2V communication. The disclosed system utilizes a machine learning (ML) model to predict the movement of vehicles in real-time traffic conditions. The disclosed system utilizes the output of the ML model for vehicle navigation, which improves the overall decision-making in real-time traffic conditions. The output of the ML model determines navigation instructions such as a lane in which the vehicle may navigate, or a speed at which the vehicle may navigate across the road segment. The navigation of the vehicle based on the determined navigation instructions enables a reduction in the power consumption by the spatial mapping sensor of the vehicle, further improving the overall range of the vehicle.

The vehicle safety while navigating is hampered due to the lack of details present in the map utilized by the set of vehicles to navigate across the road segment. The disclosed system generates a detailed and comprehensive map by utilizing the area covered by the spatial mapping sensor of each vehicle of the set of vehicles and the spatial mapping sensor of one or more infrastructures. The spatial mapping of the one or more infrastructures is mounted on each infrastructure of the one or more infrastructures. Examples of each infrastructure of the one or more infrastructures include, but are not limited to, traffic lights, road signs, and roadside light emitting devices. The disclosed system utilizes the generated detailed and comprehensive map to control at least one vehicle of the set of vehicles to navigate across the road segment, which enhances the overall safety of vehicle navigation. Previously, each vehicle of the set of vehicles utilized the area captured by the spatial mapping sensor of the respective vehicles which increased the power consumption by the spatial mapping sensor of each vehicle of the set of vehicles. The disclosed system utilizes the spatial data captured by each vehicle of the set of vehicles to generate the detailed and comprehensive map that is collectively utilized by each vehicle of the set of vehicles. The utilization of the detailed and comprehensive map decreases the power consumption by the spatial mapping sensor of each vehicle of the set of vehicles as instead of a need for each vehicle of the set of vehicles to generate the map, a collective map is generated by utilizing spatial mapping sensor data from each vehicle of the set of vehicles. The decrease in the power consumption by the spatial mapping sensor of each vehicle of the set of vehicles improves the range of at least one vehicle of the set of vehicles.

The disclosed system utilizes V2V communication and vehicle-to-infrastructure (V2I) communication to rearrange the vehicle traveling on a road segment in real-time by using real-time data such as vehicle information, road conditions, and obstacles present within the road segment (e.g., presence of a road divider). The rearrangement of the vehicle decreases power consumption by the spatial mapping sensor of each vehicle of the set of vehicles which increases the available vehicle driving range of the vehicle to reach the target destination of the vehicle.

Previously, the vehicle used to rely primarily on the spatial mapping sensor of the vehicle to capture the area of the road segment which leads to data overload in processing the spatial data captured by the spatial mapping sensor of the vehicle. The disclosed system utilizes the area of the road segment covered by the spatial mapping sensor of each vehicle of the set of vehicles, and the area of the road segment captured by the spatial mapping sensor of the infrastructure to navigate the vehicle instead of relying only on the spatial mapping sensor of the vehicle to navigate across the road segment. The disclosed system utilizes V2V communication and V2I communication to receive the spatial data captured by the spatial mapping sensor of each vehicle of the set of vehicles and the spatial mapping sensor of the infrastructure. The received spatial data is utilized to navigate the set of vehicles traveling on the road segment which further reduces data overload on the disclosed system.

Previously, the vehicle used to face delays in receiving updates on road conditions associated with the upcoming portions of the road segment, which further increases the risk of accidents, and traffic congestions. The disclosed system utilizes the V2I communication which decreases the response time for the vehicle to communicate with the infrastructure of the road segment for changes such as changes in the air quality, changes in the road lighting, or presence of obstacles (e.g., trees, poles, or road closures) which further decreases the response time of the vehicle in reacting to the changes by controlling the vehicle such as, controlling the intensity of the illumination device of the vehicle, controlling the position of the vehicle as per the presence of a road obstacle, or controlling the speed of the vehicle as per decrease in the traffic present on the road segment or presence of traffic congestion on the road segment. The decrease in the response time further improves the overall safety of vehicle navigation and reduces the possibility of traffic congestion.

In various embodiments of the disclosure, a computer-implemented method for vehicle configuration determination for vehicle navigation is described. The computer-implemented method includes receiving, by a computer, vehicle data associated with a set of vehicles present on a road segment. The vehicle data includes a speed of each vehicle of the set of vehicles, and a geographical location of each vehicle of the set of vehicles. The computer-implemented method further includes receiving, by the computer, infrastructure connectivity data associated with one or more infrastructures present on the road segment. The infrastructure connectivity data includes a geographical location of each infrastructure of the one or more infrastructures. Each infrastructure of the one or more infrastructures includes a first spatial mapping sensor. The computer-implemented method further includes receiving, by the computer, map data associated with the road segment. The computer-implemented method further includes applying, by the computer, a machine learning (ML) model to the vehicle data, the infrastructure connectivity data, and the map data. The computer-implemented method further includes determining, by the computer, a set of vehicle configurations associated with the set of vehicles based on an application of the ML model. Each vehicle configuration of the set of vehicle configurations indicates an arrangement of the set of vehicles on the road segment. The computer-implemented method further includes selecting, by the computer, a vehicle configuration from the set of vehicle configurations based on one or more criteria. The one or more criteria include one of a power consumption by a second spatial mapping sensor of each vehicle of the set of vehicles, a driving range of each vehicle of the set of vehicles, or a travel route of each vehicle of the set of vehicles. The computer-implemented method further includes controlling, by the computer, at least a first vehicle of the set of vehicles based on the selected vehicle configuration.

In various embodiments of the disclosure, the computer implemented method further includes obtaining, by the computer, a first set of power values based on the selected vehicle configuration. The computer implemented method further includes controlling, by the computer, a supply of power to a set of sensors of at least the first vehicle of the set of vehicles based on the obtained first set of power values. The set of sensors of at least the first vehicle includes the second spatial mapping sensor.

In various embodiments of the disclosure, the computer implemented method further includes obtaining, by the computer, a second set of power values associated with the selected vehicle configuration. The computer implemented method further includes transmitting, by the computer, the second set of power values to a set of sensors associated with at least one infrastructure of the one or more infrastructures. The set of sensors associated with the at least one infrastructure includes the first spatial mapping sensor. The computer implemented method further includes controlling, by the computer, a supply of power to the set of sensors of the at least one infrastructure based on the transmission of the second set of power values.

In various embodiments of the disclosure, the computer implemented method further includes generating, by the computer, a virtual representation of the set of vehicle configurations associated with the set of vehicles present on the road segment. The virtual representation is generated based on the application of the ML model to the vehicle data, the infrastructure connectivity data, and the map data. The computer implemented method further includes simulating, by the computer, the virtual representation of the set of vehicle configurations based on the one or more criteria. The computer implemented method further includes selecting, by the computer, the vehicle configuration based on a result of the simulation and the one or more criteria.

In various embodiments of the disclosure, the computer implemented method further includes controlling, by the computer, a set of sensors of the first vehicle to capture a first geographical area. The set of sensors of the first vehicle includes the second spatial mapping sensor. The computer implemented method further includes controlling, by the computer, at least one of a set of sensors of a second vehicle of the set of vehicles or a set of sensors of at least one infrastructure of the one or more infrastructures to capture a second geographical area. The set of sensors of the second vehicle includes the second spatial mapping sensor. The set of sensors of the at least one infrastructure of the one or more infrastructures includes the first spatial mapping sensor. The computer implemented method further includes determining, by the computer, a third geographical area based on the first geographical area and the second geographical area. The third geographical area corresponds to a union of the first geographical area and the second geographical area. The computer implemented method further includes generating, by the computer, a map associated with the road segment based on the third geographical area, the infrastructure connectivity data, and the map data. The map indicates a visual representation of the third geographical area. The computer implemented method further includes transmitting, by the computer, the generated map to at least the first vehicle. The computer implemented method further includes controlling, by the computer, a navigation of the first vehicle through the road segment based on the transmission of the generated map.

In various embodiments of the disclosure, the computer implemented method further includes obtaining, by the computer, atmospheric data associated with an environment of the road segment based on the selected vehicle configuration. The computer implemented method further includes applying, by the computer, the ML model to the obtained atmospheric data. The computer implemented method further includes determining, by the computer, a set of vehicle illuminance values based on the application of the ML model to the atmospheric data. The computer implemented method further includes controlling, by the computer, an intensity of light emitted by at least one light emitting device associated with at least the first vehicle. The intensity of light emitted by the at least one light emitting device associated with at least the first vehicle is controlled based on the determined set of vehicle illuminance values.

In various embodiments of the disclosure, the computer implemented method further includes determining, by the computer, a set of infrastructure illuminance values based on the application of the ML model to the atmospheric data. The computer implemented method further includes controlling, by the computer, an intensity of light emitted by one or more light emitting devices associated with at least one infrastructure of the one or more infrastructures. The intensity of light emitted by the one or more light emitting devices associated with the at least one infrastructure is controlled based on the determined set of infrastructure illuminance values. The one or more light devices illuminate at least the road segment.

In various embodiments of the disclosure, the map data includes one of a geographical location of one or more traffic signals present on the road segment, a status of each traffic signal of the one or more traffic signals, a surface quality of the road segment, a status of traffic present on the road segment, a maximum allowable speed limit for the road segment, a width of the road segment, a set of lanes within the road segment, a width of each lane of the set of lanes, or a presence of a physical divider within the road segment.

In various embodiments of the disclosure, a computer system for vehicle configuration determination for vehicle navigation is described. The computer system includes a processor set, one or more computer-readable storage media, and program instructions stored on the one or more computer-readable storage media. The program instructions are executable by the processor set and cause the processor set to receive vehicle data associated with a set of vehicles present on a road segment. The vehicle data includes a speed of each vehicle of the set of vehicles, and a geographical location of each vehicle of the set of vehicles. The program instructions further cause the processor set to receive infrastructure connectivity data associated with one or more infrastructures present on the road segment. The infrastructure connectivity data includes a geographical location of each infrastructure of the one or more infrastructures. Each infrastructure of the one or more infrastructures includes a first spatial mapping sensor. The program instructions further cause the processor set to receive map data associated with the road segment. The program instructions further cause the processor set to apply a machine learning (ML) model to the vehicle data, the infrastructure connectivity data, and the map data. The program instructions further cause the processor set to determine a set of vehicle configurations associated with the set of vehicles based on an application of the ML model. Each vehicle configuration of the set of vehicle configurations indicates an arrangement of the set of vehicles on the road segment. The program instructions further cause the processor set to select a vehicle configuration from the set of vehicle configurations based on one or more criteria. The one or more criteria include one of power consumption by a second spatial mapping sensor of each vehicle of the set of vehicles, a driving range of each vehicle of the set of vehicles, or a travel route of each vehicle of the set of vehicles. The program instructions further cause the processor set to obtain a first set of power values based on the selected vehicle configuration. The program instructions further cause the processor set to control a supply of power to a set of sensors of at least a first vehicle of the set of vehicles based on the obtained first set of power values. The set of sensors of at least the first vehicle includes the second spatial mapping sensor.

In various embodiments of the disclosure, the program instructions further cause the processor set to obtain a second set of power values associated with the selected vehicle configuration. The program instructions further cause the processor set to transmit the second set of power values to a set of sensors associated with at least one infrastructure of the one or more infrastructures. The set of sensors associated with the at least one infrastructure includes the first spatial mapping sensor. The program instructions further cause the processor set to control a supply of power to the set of sensors of the at least one infrastructure based on the transmission of the second set of power values.

In various embodiments of the disclosure, the program instructions further cause the processor set to control a supply of power to the set of sensors of the at least one infrastructure based on the transmission of the second set of power values. The program instructions further cause the processor set to simulate the virtual representation of the set of vehicle configurations based on the one or more criteria. The program instructions further cause the processor set to select the vehicle configuration based on a result of the simulation and the one or more criteria.

In various embodiments of the disclosure, the program instructions further cause the processor set to control the set of sensors of the first vehicle to capture a first geographical area. The set of sensors of the first vehicle includes the second spatial mapping sensor. The program instructions further cause the processor set to control at least one of a set of sensors of a second vehicle of the set of vehicles or a set of sensors of at least one infrastructure of the one or more infrastructures to capture a second geographical area. The set of sensors of the second vehicle includes the second spatial mapping sensor. The set of sensors of the at least one infrastructure of the one or more infrastructures includes the first spatial mapping sensor. The program instructions further cause the processor set to determine a third geographical area based on the first geographical area and the second geographical area. The third geographical area corresponds to a union of the first geographical area and the second geographical area. The program instructions further cause the processor set to generate a map associated with the road segment based on the third geographical area, the infrastructure connectivity data, and the map data. The map indicates a visual representation of the third geographical area. The program instructions further cause the processor set to transmit the generated map to at least the first vehicle. The program instructions further cause the processor set to control a navigation of the first vehicle through the road segment based on the transmission of the generated map.

In various embodiments of the disclosure, the program instructions further cause the processor set to obtain atmospheric data associated with an environment of the road segment based on the selected vehicle configuration. The program instructions further cause the processor set to apply the ML model to the obtained atmospheric data. The program instructions further cause the processor set to determine a set of vehicle illuminance values based on the application of the ML model to the atmospheric data. The program instructions further cause the processor set to control an intensity of light emitted by at least one light emitting device associated with at least the first vehicle. The intensity of light emitted by the at least one light emitting device associated with at least the first vehicle is controlled based on the determined set of vehicle illuminance values.

In various embodiments of the disclosure, the program instructions further cause the processor set to determine a set of infrastructure illuminance values based on the application of the ML model to the atmospheric data. The program instructions further cause the processor set to control an intensity of light emitted by one or more light emitting devices associated with at least one infrastructure of the one or more infrastructures. The intensity of light emitted by the one or more light emitting devices associated with the at least one infrastructure is controlled based on the determined set of infrastructure illuminance values. The one or more light devices illuminate at least the road segment.

In various embodiments of the disclosure, the map data includes one of a geographical location of one or more traffic signals present on the road segment, a status of each traffic signal of the one or more traffic signals, a surface quality of the road segment, a status of traffic present on the road segment, a maximum allowable speed limit for the road segment, a width of the road segment, a set of lanes within the road segment, a width of each lane of the set of lanes, or a presence of a physical divider within the road segment.

In various embodiments of the disclosure, a computer-program product for vehicle configuration determination for controlling vehicle navigation of at least one vehicle is described. The computer program product includes one or more computer-readable storage media and program instructions stored in the one or more computer-readable storage media to perform operations that include receiving vehicle data associated with a set of vehicles present on a road segment. The vehicle data includes a speed of each vehicle of the set of vehicles, and a geographical location of each vehicle of the set of vehicles. The operations further include receiving infrastructure connectivity data associated with one or more infrastructures present on the road segment. The infrastructure connectivity data includes a geographical location of each infrastructure of the one or more infrastructures. Each infrastructure of the one or more infrastructures includes a first spatial mapping sensor. The operations further include receiving map data associated with the road segment. The operations further include applying a machine learning (ML) model to the vehicle data, the infrastructure connectivity data, and the map data. The operations further include determining a set of vehicle configurations associated with the set of vehicles based on an application of the ML model. Each vehicle configuration of the set of vehicle configurations indicates an arrangement of the set of vehicles on the road segment. The operations further include selecting a vehicle configuration from the set of vehicle configurations based on one or more criteria. The one or more criteria include one of power consumption by a second spatial mapping sensor of each vehicle of the set of vehicles, a driving range of each vehicle of the set of vehicles, or a travel route of each vehicle of the set of vehicles. The operations further include controlling the at least one vehicle of the set of vehicles based on the selected vehicle configuration.

In various embodiments of the disclosure, the operations further include obtaining a first set of power values associated with the selected vehicle configuration. The operations further include controlling a supply of power to a set of sensors of at least a first vehicle of the set of vehicles based on the obtained first set of power values. The set of sensors of at least the first vehicle includes the second spatial mapping sensor.

In various embodiments of the disclosure, the operations further include obtaining a second set of power values associated with the selected vehicle configuration. The operations further include transmitting the second set of power values to a set of sensors associated with at least one infrastructure of the one or more infrastructures. The set of sensors associated with the at least one infrastructure includes the first spatial mapping sensor. The operations further include controlling a supply of power to the set of sensors of the at least one infrastructure based on the transmission of the second set of power values.

In various embodiments of the disclosure, the operations further include generating a virtual representation of the set of vehicle configurations associated with the set of vehicles present on the road segment. The virtual representation is generated based on the application of the ML model to the vehicle data, the infrastructure connectivity data, and the map data. The operations further include simulating the virtual representation of the set of vehicle configurations based on the one or more criteria. The operations further include selecting the vehicle configuration based on a result of the simulation and the one or more criteria.

In various embodiments of the disclosure, the map data includes one of a geographical location of one or more traffic signals present on the road segment, a status of each traffic signal of the one or more traffic signals, a surface quality of the road segment, a status of traffic present on the road segment, a maximum allowable speed limit for the road segment, a width of the road segment, a set of lanes within the road segment, a width of each lane of the set of lanes, or a presence of a physical divider within the road segment.

Various aspects of the disclosure are described by narrative text, flowcharts, block diagrams of computer systems, and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks are performed in reverse order, as a single integrated operation, concurrently, or in a manner at least partially overlapping in time.

A computer program product embodiment (“CPP embodiment” or “CPP”) is a term used in the disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer-readable storage media is an electronic storage media, a magnetic storage media, an optical storage media, an electromagnetic storage media, a semiconductor storage media, a mechanical storage media, or any suitable combination of the foregoing. Some known types of storage devices that include these mediums include diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer-readable storage media or mediums, as that term is used in the disclosure, is not to be construed as storage in the form of transitory signals per se, such as radio waves or various freely propagating electromagnetic waves, electromagnetic waves propagating through a waveguide, light pulses passing through a fiber optic cable, electrical signals communicated through a wire, and/or various transmission media. As will be understood by those of skill in the art, data is typically moved at some occasional points in time during normal operations of a storage device, such as during access, de-fragmentation, or garbage collection, but this does not render the storage device as transitory because the data is not transitory while stored.

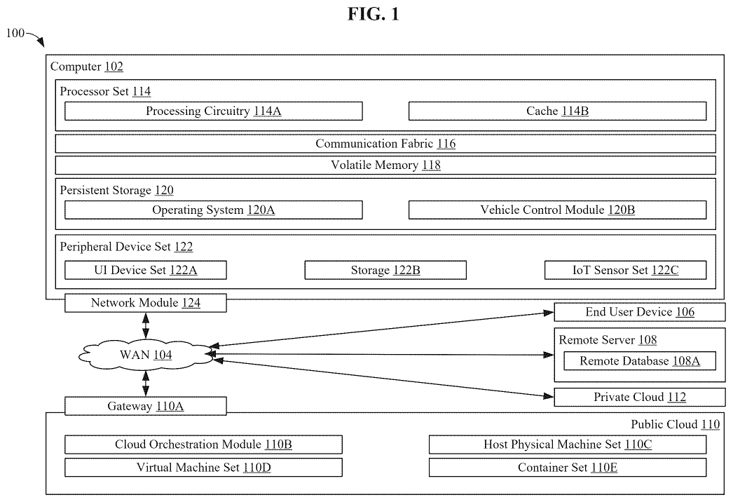

FIG. 1 is a diagram that illustrates a computing environment for vehicle configuration determination for vehicle navigation, in accordance with an embodiment of the disclosure. With reference to FIG. 1, there is shown a computing environment 100 that contains an example of an environment for the execution of at least some of the computer code involved in performing the disclosed methods, such as a vehicle control module 120B. In addition to the vehicle control module 120B, computing environment 100 includes, for example, a computer 102, a wide area network (WAN) 104, an end user device (EUD) 106, a remote server 108, a public cloud 110, and a private cloud 112. In this embodiment of the disclosure, the computer 102 includes a processor set 114 (including a processing circuitry 114A and a cache 114B), a communication fabric 116, a volatile memory 118, a persistent storage 120 (including an operating system 120A and the vehicle control module 120B, as identified above), a peripheral device set 122 (including a user interface (UI) device set 122A, a storage 122B, and an Internet of Things (IoT) sensor set 122C), and a network module 124. The remote server 108 includes a remote database 108A. The public cloud 110 includes a gateway 110A, a cloud orchestration module 110B, a host physical machine set 110C, a virtual machine set 110D, and a container set 110E.

The computer 102 may take the form of a desktop computer, a laptop computer, a tablet computer, a smartphone, a smartwatch or a wearable computer, a mainframe computer, a quantum computer, or any various forms of a computer or a mobile device now known or to be developed in the future that can run a program, access a network or query a database, such as the remote database 108A. As is well understood in the art of computer technology, and depending upon the technology, the performance of a computer-implemented method may be distributed among multiple computers and/or between multiple locations. In this presentation of the computing environment 100, detailed discussion is focused on a single computer, specifically the computer 102, to keep the presentation as simple as possible. The computer 102 may be located in a cloud, even though not shown in a cloud in FIG. 1.

The processor set 114 includes one, or more, computer processors of any type now known or to be developed in the future. The processing circuitry 114A may be distributed over multiple packages, for example, multiple, coordinated integrated circuit chips. The processing circuitry 114A may implement multiple processor threads and/or multiple processor cores. The cache 114B is a memory that is located in the processor chip package(s) and is typically used for data or code that should be available for rapid access by the threads or cores running on the processor set 114. Cache memories are typically organized into multiple levels depending upon relative proximity to the processing circuitry 114A. Alternatively, some, or all, of the cache 114B for the processor set 114 may be located “off-chip.” In some computing environments, the processor set 114 may be designed for working with qubits and performing quantum computing.

Computer readable program instructions are typically loaded onto the computer 102 to cause a series of operations to be performed by the processor set 114 of the computer 102 and thereby effect a computer-implemented method, such that the instructions thus executed will instantiate the methods specified in flowcharts and/or narrative descriptions of computer-implemented methods included in this document (collectively referred to as “the disclosed methods”). These computer-readable program instructions are stored in various types of computer-readable storage media, such as the cache 114B and the various storage media discussed below. The program instructions, and associated data, are accessed by the processor set 114 to control and direct the performance of the disclosed methods. In computing environment 100, at least some of the instructions for performing the disclosed methods may be stored in the dynamic modification of the vehicle control module 120B in persistent storage 120.

The communication fabric 116 is the signal conduction path that allows the various components of the computer 102 to communicate with each other. Typically, this fabric is made of switches and electrically conductive paths, such as the switches and electrically conductive paths that make up buses, bridges, physical input/output ports, and the like. Various types of signal communication paths are used, such as fiber optic communication paths and/or wireless communication paths.

The volatile memory 118 is any type of volatile memory now known or to be developed in the future. Examples include dynamic type random access memory (RAM) or static type RAM. Typically, the volatile memory 118 is characterized by random access, but this is not needed unless affirmatively indicated. In the computer 102, the volatile memory 118 is located in a single package and is internal to the computer 102, but alternatively or additionally, the volatile memory 118 may be distributed over multiple packages and/or located externally with respect to the computer 102.

The persistent storage 120 is any form of non-volatile storage for computers that is now known or to be developed in the future. The non-volatility of this storage means that the stored data is maintained regardless of whether power is being supplied to the computer 102 and/or directly to the persistent storage 120. The persistent storage 120 is a read-only memory (ROM), but typically at least a portion of the persistent storage 120 allows the writing of data, deletion of data, and re-writing of data. Some familiar forms of the persistent storage 120 include magnetic disks and solid-state storage devices. The operating system 120A may take several forms, such as various known proprietary operating systems or open-source Portable Operating System Interface-type operating systems that employ a kernel. The code included in the vehicle control module 120B typically includes at least some of the computer code involved in performing the disclosed methods.

The peripheral device set 122 includes the set of peripheral devices of the computer 102. Data communication connections between the peripheral devices and the various components of the computer 102 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments of the disclosure, the UI device set 122A includes components such as a display screen, speaker, microphone, wearable devices (such as goggles and smartwatches), keyboard, mouse, printer, touchpad, game controllers, and haptic devices. The storage 122B is external storage, such as an external hard drive, or insertable storage, such as an SD card. The storage 122B is persistent and/or volatile. In some embodiments of the disclosure, the storage 122B may take the form of a quantum computing storage device for storing data in the form of qubits. In embodiments of the disclosure where the computer 102 is needed to have a large amount of storage (for example, where the computer 102 locally stores and manages a large database) then this storage may be provided by peripheral storage devices designed for storing very large amounts of data, such as a storage area network (SAN) that is shared by multiple, geographically distributed computers. The IoT sensor set 122C is made up of sensors that can be used in Internet of Things applications. For example, a first sensor may be a thermometer, and a second sensor may be a motion detector.

The network module 124 is the collection of computer software, hardware, and firmware that allows the computer 102 to communicate with various computers through the WAN 104. The network module 124 may include hardware, such as modems or Wi-Fi signal transceivers, software for packetizing and/or de-packetizing data for communication network transmission, and/or web browser software for communicating data over the internet. In some embodiments of the disclosure, network control functions, and network forwarding functions of the network module 124 are performed on the same physical hardware device. In various embodiments of the disclosure (for example, embodiments that utilize software-defined networking (SDN)), the control functions and the forwarding functions of the network module 124 are performed on physically separate devices, such that the control functions manage several different network hardware devices. Computer-readable program instructions for performing the disclosed methods can typically be downloaded to the computer 102 from an external computer or external storage device through a network adapter card or network interface included in the network module 124.

The WAN 104 is any wide area network (for example, the internet) for communicating computer data over non-local distances by any technology for communicating computer data, now known or to be developed in the future. In some embodiments of the disclosure, the WAN 104 may be replaced and/or supplemented by local area networks (LANs) designed to communicate data between devices located in a local area, such as a Wi-Fi network. The WAN 104 and/or LANs typically include computer hardware such as copper transmission cables, optical transmission fibers, wireless transmission, routers, firewalls, switches, gateway computers, and edge servers.

The EUD 106 is any computer system that is used and controlled by an end user (for example, a customer of an enterprise that operates the computer 102) and may take any of the forms discussed above in connection with the computer 102. The EUD 106 typically receives helpful and useful data from the operations of the computer 102. For example, in a hypothetical case where the computer 102 is designed to provide a recommendation to an end user, this recommendation would typically be communicated from the network module 124 of the computer 102 through the WAN 104 to the EUD 106. In this way, the EUD 106 can display, or otherwise present recommendations to an end user. In some embodiments of the disclosure, the EUD 106 may be a client device, such as a mainframe computer, desktop computer, and so on.

The remote server 108 is any computer system that serves at least some data and/or functionality to the computer 102. The remote server 108 may be controlled and used by the same entity that operates the computer 102. The remote server 108 represents the machine(s) that collect and store helpful and useful data for use by various computers, such as the computer 102. For example, in a hypothetical case where the computer 102 is designed and programmed to provide a recommendation based on historical data, then this historical data may be provided to the computer 102 from the remote database 108A of the remote server 108.

The public cloud 110 is any computer system available for use by multiple entities that provides on-demand availability of computer system resources and/or various computer capabilities, especially data storage (cloud storage) and computing power, without direct active management by the user. Cloud computing typically leverages the sharing of resources to achieve coherence and economies of scale. The direct and active management of the computing resources of the public cloud 110 is performed by the computer hardware and/or software of the cloud orchestration module 110B. The computing resources provided by the public cloud 110 are typically implemented by virtual computing environments that run on various computers making up the computers of the host physical machine set 110C, which is the universe of physical computers in and/or available to the public cloud 110. The virtual computing environments (VCEs) typically take the form of virtual machines from the virtual machine set 110D and/or containers from the container set 110E. It is understood that these VCEs may be stored as images and may be transferred among and between the various physical machine hosts, either as images or after the instantiation of the VCE. The cloud orchestration module 110B manages the transfer and storage of images, deploys new instantiations of VCEs, and manages active instantiations of VCE deployments. The gateway 110A is the collection of computer software, hardware, and firmware that allows the public cloud 110 to communicate through the WAN 104.

Some further explanation of virtualized computing environments (VCEs) will now be provided. VCEs can be stored as “images”. A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in the containers. A computer program running on an ordinary operating system can utilize the resources of that computer, such as connected devices, files and folders, network shares, CPU power, and quantifiable hardware capabilities. However, programs running inside a container can only use the contents of the container and devices assigned to the container, a feature which is known as containerization.

The private cloud 112 is similar to the public cloud 110, except that the computing resources are only available for use by a single enterprise. While the private cloud 112 is shown as being in communication with the WAN 104, in various embodiments of the disclosure, a private cloud may be disconnected from the internet entirely and only accessible through a local/private network. A hybrid cloud is a composition of multiple clouds of different types (for example, private, community, or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment of the disclosure, the public cloud 110 and the private cloud 112 are both part of a larger hybrid cloud.

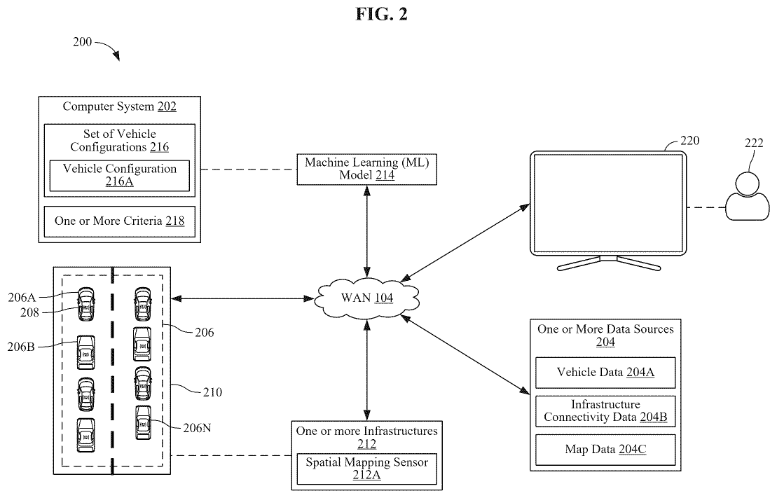

FIG. 2 is a diagram that illustrates an environment for vehicle configuration determination for vehicle navigation, in accordance with an embodiment of the disclosure. FIG. 2 is explained in conjunction with elements from FIG. 1. With reference to FIG. 2, there is shown a diagram of a network environment 200. The network environment 200 includes a computer system 202, one or more data sources 204, a set of vehicles 206, a road segment 210, one or more infrastructures 212, and a machine learning (ML) model 214. The computer system 202 includes a set of vehicle configurations 216 and one or more criteria 218. The one or more data sources 204 include vehicle data 204A, infrastructure connectivity data 204B, and map data 204C. The set of vehicles 206 includes a first vehicle 206A, a second vehicle 206B, up to Nth vehicle 206N. The first vehicle 206A includes a specific spatial mapping sensor 208. Each infrastructure of the one or more infrastructures includes a spatial mapping sensor 212A. The set of vehicle configurations 216 includes a vehicle configuration 216A. The network environment 200 further includes a user device 220, and a user 222 associated with the user device 220. The network environment 200 further includes the WAN 104 of FIG. 1. In an embodiment of the disclosure, the user device 220 is an exemplary embodiment of the EUD 106. Similarly, the computer system 202 is an exemplary embodiment of the computer 102 in FIG. 1.

The computer system 202 includes suitable logic, circuitry, and/or interfaces for vehicle configuration determination for vehicle navigation, in accordance with an embodiment of the disclosure. The computer system 202 receives the vehicle data 204A associated with the set of vehicles 206 present on the road segment 210. The vehicle data 204A includes at least the speed of each vehicle of the set of vehicles 206 and a geographical location of each vehicle of the set of vehicles 206. The computer system 202 further receives the infrastructure connectivity data 204B associated with one or more infrastructures 212 present on the road segment 210. The infrastructure connectivity data 204B includes at least a geographical location of each infrastructure of the one or more infrastructures 212. Each infrastructure of the one or more infrastructures 212 includes at least the spatial mapping sensor 212A. The computer system 202 further receives the map data 204C associated with the road segment 210. The computer system 202 further applies the ML model 214 to the vehicle data 204A, the infrastructure connectivity data 204B, and the map data 204C. The computer system 202 further determines the set of vehicle configurations 216 associated with the set of vehicles 206 based on the application of the ML model 214. Each vehicle configuration of the set of vehicle configurations 216 indicates an arrangement of the set of vehicles 206 on the road segment 210. The computer system 202 further selects the vehicle configuration 216A from the set of vehicle configurations 216 based on the one or more criteria 218. The one or more criteria 218 include at least one of power consumption by the spatial mapping sensor of each vehicle of the set of vehicles 206, a driving range of each vehicle of the set of vehicles 206, or a travel route of each vehicle of the set of vehicles 206. The computer system 202 further controls at least the first vehicle 206A of the set of vehicles 206 based on the selected vehicle configuration 216A.

Examples of the computer system 202 include but are not limited to, a server, a computing device, a mainframe machine, a computer workstation, an electronic control unit (ECU), an electronic control module (ECM), a cloud-based service, a remote server-based service, or a virtual computing system.

Each data source of the one or more data sources 204 corresponds to an organized collection of data that may be stored and accessed electronically from a computer system (such as the computer system 202). Each of the one or more data sources 204 may be designed to manage, store, retrieve, and update data efficiently. In an exemplary implementation, each data source of the one or more data sources 204 may correspond to a database. In such an implementation, the structure of the database corresponding to each data source of the one or more data sources 204 typically involves tables, records, and fields that can be managed through various database management systems (DBMS). Examples of each data source of one or more data sources 204 may include but are not limited to, a relational database, a Non-Structured Query Language (NoSQL) database, a hierarchical database, a network database, a transactional database, a data warehouse, and a distributed database.

In an embodiment of the disclosure, at least one data source of the one or more data sources 204 corresponds to a map database. In an embodiment of the disclosure, the map database corresponds to a database that stores the vehicle data 204A, the infrastructure connectivity data 204B, and the map data 204C. In an embodiment of the disclosure, the vehicle data 204A, the infrastructure connectivity data 204B, and the map data 204C may be updated in real-time or near real-time to provide accurate and up-to-date data associated with the road segment 210. The gathering of massive quantities of crowd-sourced data may ensure the accurate modeling and mapping of an environment, whether the environment is associated with a road link or a link within a structure, such as a conjunction of a plurality of road segments. Cloud-sourced data refers to information associated with the environment of the road segment 210 that is collected from a group of individuals. The map database further stores traffic-related data and road topology and geometry-related data for a road network (e.g., the road segment 210).

The vehicle data 204A refers to information that is exchanged between each vehicle of the set of vehicles 206. The vehicle data 204A is exchanged in real-time through, by way of example, and not by limitation, the WAN 104. The vehicle data 204A includes, by way of example, and not by limitation, the geographical coordinates of each vehicle of the set of vehicles 206, the speed of each vehicle of the set of vehicles 206, and a heading direction of each vehicle of the set of vehicles 206. The vehicle data 204A further includes, by way of example, but not limited to, acceleration of each vehicle of the set of vehicles 206, braking associated with each vehicle of the set of vehicles 206, fuel consumption of each vehicle of the set of vehicles 206, and engine performance of each vehicle of the set of vehicles 206. Each vehicle of the set of vehicles 206 includes at least the spatial mapping sensor. For example, the first vehicle 206A includes the specific spatial mapping sensor 208. The spatial mapping sensor is a device that measures distances and captures spatial data to create accurate three-dimensional representations of the environment of the road segment 210. Examples of the spatial mapping sensor include, by way of example, and not by limitation, light detection and ranging (LiDAR) sensors, radio detection and ranging (RADAR) sensors, image capture sensors, and ultrasonic sensors.

The infrastructure connectivity data 204B refers to information that is exchanged between each vehicle of the set of vehicles 206 and the one or more infrastructures 212 associated with the road segment 210. In an embodiment of the disclosure, the infrastructure connectivity data 204B is stored in the one or more data sources 204 (e.g., the map database). The infrastructure connectivity data 204B is exchanged in real-time through, by way of example, and not by limitation, the WAN 104. The infrastructure connectivity data 204B includes at least the geographical location of each infrastructure of the one or more infrastructures 212. Each infrastructure of the one or more infrastructures 212 includes at least the spatial mapping sensor 212A. The spatial mapping sensor is a device that measures distances and captures spatial data to create accurate three-dimensional representations of the environment of the road segment 210. Examples of the spatial mapping sensor include, by way of example, and not by limitation, light detection and ranging (LiDAR) sensors, radio detection and ranging (RADAR) sensors, image capture sensors, and ultrasonic sensors.

In an embodiment of the disclosure, the infrastructure connectivity data 204B includes atmospheric data including, by way of example, and not by limitation, the presence of dust in the environment of the road segment 210, a humidity level in the environment of the road segment 210, a pressure of air in the environment of the road segment 210, a temperature value of the environment of the road segment 210, a presence of precipitation across the road segment 210, visibility across the road segment 210, and a wind speed associated with the road segment 210.

The map data 204C includes at least one of the geographical location of one or more traffic signals present on the road segment 210, a status of each traffic signal of the one or more traffic signals, a surface quality of the road segment 210, a status of traffic present on the road segment 210, a maximum allowable speed limit for the road segment 210, a width of the road segment 210, a set of lanes within the road segment 210, a width of each lane of the set of lanes, or a presence of a physical divider within the road segment 210.

The status of each traffic signal of the one or more traffic signals refers to an operational state of a traffic control signal that controls the flow of traffic on the road segment 210. The traffic signal status indicates signal indications (e.g., stop, wait, and go) that determine the priority for movement of the set of vehicles 206 and/or pedestrians across the road segment 210. The surface quality of the road segment 210 includes characteristics of the surface of the road segment 210, which may include factors such as texture, friction, smoothness, and the presence of defects or hazards on the road segment 210 (e.g., potholes, cracks, ice, or debris). The status of the traffic present on the road segment 210 indicates a real-time assessment of the movement of the set of vehicles 206 and the movement of pedestrians within a specific section of the road segment 210. The maximum allowable speed limit for the road segment 210 indicates the maximum speed at which any vehicle of the set of vehicles 206 may travel across the road segment 210 as defined by the national highway traffic safety administration (NHTSA). The width of the road segment 210 indicates a horizontal distance measured across the edges of the road segment 210. The set of lanes within the road segment 210 indicates a count of lanes present within the road segment 210. The presence of the physical divider within the road segment 210 is a structural element present within the road segment 210 that separates the set of lanes present within the road segment 210.

The map data 204C further includes by way of example, and not by limitation, locations of intersections present on the road segment 210, diversions to be caused on the road segment 210 due to accidents, congestions or constructions present on the road segment 210, and road closures present on the road segment 210. In an embodiment of the disclosure, the map data 204C stored in the map database may further include data about changes in traffic situations registered by global positioning system (GPS) provider(s), such as, but not limited to, incidents, road repairs, heavy rains, snow, fog, time of day, day of a week, holiday or events which may influence the traffic condition of the road segment 210.

Each vehicle of the set of vehicles 206 such as the first vehicle 206A may be a non-autonomous vehicle, a semi-autonomous vehicle, or a fully autonomous vehicle, for example, as defined by the national highway traffic safety administration (NHTSA). Examples of the first vehicle 206A may include, but are not limited to, a two-wheeler electric vehicle, a three-wheeler electric vehicle, a four-wheeler electric vehicle, or more than a four-wheeler electric vehicle. Examples of two-wheeler vehicles may include, but are not limited to, an electric two-wheeler, or a hybrid two-wheeler. Similarly, examples of the four-wheeler vehicle may include, but are not limited to, an electric car, or a hybrid car. The description of types of vehicles and respective structures, designs, or shapes has been omitted from the disclosure for the sake of brevity.

By way of example, and not by limitation, the first vehicle 206A includes processing means such as a central processing unit (CPU), storage means such as on-board read-only memory (ROM), and random access memory (RAM), acoustic sensors such as a microphone array, position sensors such as a global positioning system (GPS) sensor, gyroscope, a light detection and ranging (LiDAR) sensor, a proximity sensor, motion sensors such as an accelerometer, an image sensor such as a camera, a display enabled user interface such as a touch screen display, and components as may be vital for specific functionalities of the first vehicle 206A.

By way of example, and not by limitation, the first vehicle 206A may be associated with one or more user equipment, coupled, or otherwise integrated with the first vehicle 206A, such as an advanced driver assistance system (ADAS), a personal navigation device (PND), a portable navigation device, and/or devices that may be configured to provide route guidance and navigation-related functions to the user 222.

In an embodiment of the disclosure, each vehicle of the set of vehicles 206 includes the spatial mapping sensor. In an embodiment of the disclosure, the spatial mapping sensor corresponds to a LiDAR sensor. The LiDAR sensor is a remote sensing technology that utilizes laser light to measure distances and create high-resolution, three-dimensional representations of the environment. The LiDAR sensor emits rapid pulses of laser light, which travel to a target and reflect to the LiDAR sensor. The LiDAR sensor determines the distance to the object by calculating the time taken by the rapid pulses of the laser light to return to the LiDAR sensor. The LiDAR sensor includes a laser source, a receiver (or detector), and a positioning system, such as GPS and inertial measurement units, which ensures accurate georeferencing of the collected data.

LiDAR sensors are essential for autonomous vehicles as the LiDAR sensors provide precise environmental perception, which is crucial for safe navigation and decision-making. LiDAR sensors detect and classify objects present in the environment of the road segment 210. Further, the LiDAR sensor measures the distance between the LiDAR sensor and the objects and generates detailed 3D maps of the environment of the road segment 210. The utilization of LiDAR sensors is vital for identifying obstacles, pedestrians, and vehicles present on the road segment 210 which allows accurate path planning and collision avoidance between the set of vehicles.

The road segment 210 may include any route between two locations that allows travel by way of example, and not by limitation, foot, and the set of vehicles 206. Examples of the road segment 210 may include, but are not limited to, streets, highways, freeways, trails, bridges, tunnels, toll roads, and/or crossings. In an embodiment of the disclosure, the road segment 210 may include a set of intersections. Each intersection of the set of intersections may correspond to a section of the road segment 210 that allows users associated with the set of vehicles 206 to travel from the road segment 210 to different road segments.

Each infrastructure of the one or more infrastructures 212 includes an integrated system that enables real-time data exchange between the set of vehicles 206 and the one or more infrastructures 212 to enhance safety and traffic efficiency. In an embodiment of the disclosure, each infrastructure of the one or more infrastructures 212 includes at least the spatial mapping sensor 212A (e.g., the LiDAR sensor). Each infrastructure of one or more infrastructures 212 corresponds to, by way of example, and not by limitation, road lighting systems, traffic management systems, pedestrian safety systems, and environmental monitoring systems.

The ML model 214 corresponds to a computational network or a system of artificial neurons, arranged in a plurality of layers, as nodes. The plurality of layers of the ML model 214 may include an input layer, one or more hidden layers, and an output layer. Each layer of the plurality of layers may include one or more nodes (or artificial neurons). Outputs of nodes present in the input layer may be coupled to at least one node of the hidden layer(s). Similarly, inputs of each hidden layer may be coupled to outputs of at least one node in a plurality of layers of the ML model 214. Outputs of each hidden layer may be coupled to inputs of at least one node in the plurality of layers of the ML model 214. Node(s) in the final layer may receive inputs from at least one hidden layer to output a result. The number of layers and the number of nodes in each layer may be determined from the hyper-parameters of the ML model 214. Such hyper-parameters may be set before or while training the ML model 214 on a training dataset.

Each node of the ML model 214 may correspond to a mathematical function (e.g., a sigmoid function or a rectified linear unit) with a set of parameters, tunable during the training of the network. The set of parameters may include, for example, a weight parameter, a regularization parameter, and the like. Each node may use the mathematical function to compute an output based on one or more inputs from nodes in the plurality of layer(s) (e.g., previous layer(s)) of the ML model 214. Every or some of the nodes of the ML model 214 may correspond to the same or a different mathematical function.

In training the ML model 214, one or more parameters of each node of the ML model 214 may be updated based on whether an output of the final layer for a given input (from the training dataset) matches a correct result based on a loss function for the ML model 214. The above process may be repeated for the same or a different input until a minima of loss function may be achieved, and a training error may be minimized. Several methods for training are known in the art, for example, gradient descent, stochastic gradient descent, batch gradient descent, gradient boost, meta-heuristics, and the like.

The ML model 214 may include electronic data, such as, for example, a software program, code of the software program, libraries, applications, scripts, or logic or instructions for execution by a processing device, such as a processor set. The ML model 214 may include code and routines configured to enable a computing device, such as the computer system 202 to perform one or more operations. Additionally, or alternatively, the ML model 214 may be implemented using hardware including a processor, a microprocessor (e.g., to perform or control the performance of one or more operations), a field-programmable gate array (FPGA), or an application-specific integrated circuit (ASIC). Alternatively, in some embodiments, the ML model 214 may be implemented using a combination of hardware and software. Although in FIG. 2, the ML model 214 is shown as a separate entity from the computer system 202, the disclosure is not so limited. Accordingly, in some embodiments, the ML model 214 may be integrated within the computer system 202, without deviation from the scope of the disclosure. Examples of the ML model 214 may include, but are not limited to, a deep neural network (DNN), a convolutional neural network (CNN), a CNN-recurrent neural network (CNN-RNN), an artificial neural network (ANN), a fully connected neural network, and/or a combination of such networks.

Each vehicle configuration of the set of vehicle configurations 216 (e.g., the vehicle configuration 216A) corresponds to the arrangement and positioning of the set of vehicles 206 within the road segment 210, including spatial orientation, dimensions, and alignment of at least the first vehicle 206A relative to the set of vehicles 206 and the one or more infrastructures 212 of the road segment 210. Each configuration of the set of vehicle configurations 216 includes factors such as the length of each vehicle of the set of vehicles 206, width of each vehicle of the set of vehicles 206, height of each vehicle of the set of vehicles 206, and wheelbase of each vehicle of the set of vehicles 206, as well as placement of each vehicle of the set of vehicles 206 in relation to lane markings, traffic signals, and road elements (e.g., roadside lighting pole).

The one or more criteria 218 includes at least one of the power consumption by the spatial mapping sensor of each vehicle of the set of vehicles 206, the driving range of each vehicle of the set of vehicles 206, or the travel route of each vehicle of the set of vehicles 206. The power consumption by the spatial mapping sensor of each vehicle of the set of vehicles 206 corresponds to a power value that is utilized by the spatial mapping sensor to capture at least a portion of the geographical area associated with the road segment 210. By way of example, and not by limitation, the power consumption is measured in watts (e.g., 10 watts). The driving range corresponds to a maximum distance that the first vehicle 206A may travel based on the amount of charge present in the battery of the first vehicle 206A. By way of example, and not by limitation, the driving range of the first vehicle 206A is 200 kilometers for 90 percent charge present in the battery of the first vehicle 206A. The travel route corresponds to a defined path that is taken by the first vehicle 206A to reach a specific destination. The travel route includes, by way of example, and not by limitation, a starting point of the journey of the first vehicle 206A, an ending point of the journey of the first vehicle 206A, a distance between the starting point of the journey of the first vehicle 206A and the ending point of the journey of the first vehicle 206A, a travel time associated with the completion of the journey, and navigation instructions to navigate the first vehicle 206A on the road segment 210 (e.g., taking an exit from a specific exit point present on the road segment 210).

The user device 220 includes suitable logic, circuitry, and/or interfaces that are configured to execute one or more tasks within the network environment 200. The user device 220 performs the one or more tasks such as receiving data, processing the data, and transmitting the data. Examples of the user device 220 include one but are not limited to, a computer workstation, a laptop, a smartphone, a mobile phone, a consumer electronic (CE) device, an Internet of Things (IoT) device, a computing device, a mainframe machine, and a server. In an embodiment of the disclosure, the user device 220 corresponds to a touch-sensitive liquid crystal display present within the first vehicle 206A that is utilized to display a map. The displayed map is utilized to navigate the first vehicle 206A on the road segment 210.

In operation, the computer system 202 receives the vehicle data 204A associated with the set of vehicles 206 present on the road segment 210. The vehicle data 204A includes at least the speed of each vehicle of the set of vehicles 206 and the geographical location of each vehicle of the set of vehicles 206. By way of example, and not by limitation, the set of vehicles includes vehicles D, E, and F. The vehicle data 204A includes the speed of vehicle D, the speed of vehicle E, the speed of vehicle F, the geographical location of the vehicle D, the geographical location of the vehicle E, and the geographical location of the vehicle F.

The computer system 202 further receives the infrastructure connectivity data 204B associated with the one or more infrastructures 212 present on the road segment 210. The infrastructure connectivity data 204B includes at least the geographical location of each infrastructure of the one or more infrastructures 212. Each infrastructure of the one or more infrastructures 212 includes at least the spatial mapping sensor 212A. By way of example, and not by limitation, the one or more infrastructures 212 include infrastructures P, Q, and R. The infrastructure connectivity data 204B includes the geographical location of the infrastructure P, the geographical location of the infrastructure Q, and the geographical location of the infrastructure R.

The computer system 202 further receives the map data 204C associated with the road segment 210. The computer system 202 further applies the ML model 214 to the vehicle data 204A, the infrastructure connectivity data 204B, and the map data 204C. The computer system 202 further determines the set of vehicle configurations 216 associated with the set of vehicles 206 based on the application of the ML model 214. Each vehicle configuration of the set of vehicle configurations 216 indicates an arrangement of the set of vehicles 206 on the road segment 210. By way of example, and not by limitation, the set of vehicle configurations 216 of the set of vehicles 206 includes vehicle configurations I, J, K, and L.

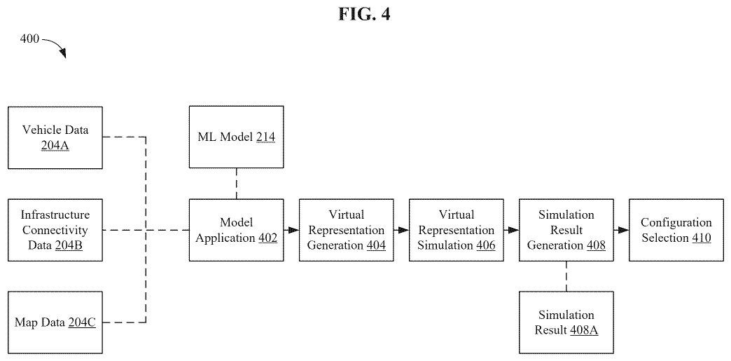

The computer system 202 further selects the vehicle configuration 216A from the set of vehicle configurations 216 based on the one or more criteria 218. The one or more criteria 218 include at least one of power consumption by the spatial mapping sensor of each vehicle of the set of vehicles 206, a driving range of each vehicle of the set of vehicles 206, or a travel route of each vehicle of the set of vehicles 206. In an embodiment of the disclosure, the computer system 202 configurations 216segment 210model 214configurations 216criteria 218selects the vehicle configuration 216A based on the one or more criteria 218 and a result of the simulation of virtual representation of the set of vehicle configurations 216criteria 218. Details about selecting the vehicle configuration 216A from the set of vehicle configurations 216 based on the one or more criteria 218 and the result of the simulation of virtual representation of the set of vehicle configurations 216 are provided, in FIG. 4, and its corresponding description.

The computer system 202 further controls at least the first vehicle 206A of the set of vehicles 206 based on the selected vehicle configuration 216A. By way of example, and not by limitation, the computer system 202 controls the first vehicle 206A by navigating the first vehicle 206A from lane P of the road segment 210 to lane Q of the road segment 210 based on the vehicle configuration 216A.

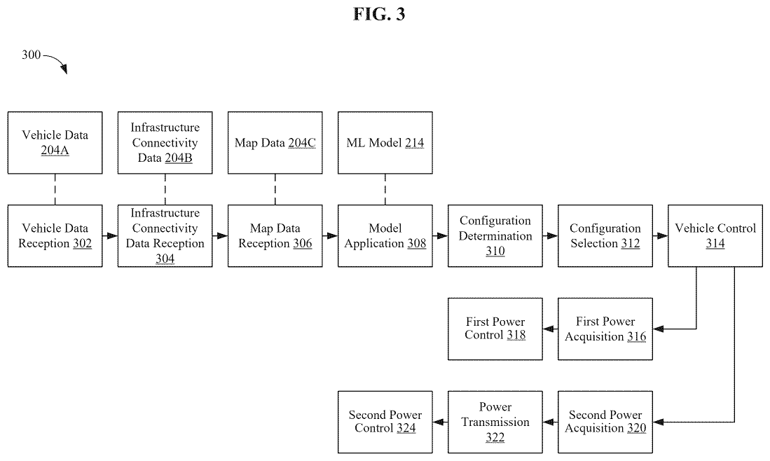

FIG. 3 is a diagram that illustrates a first set of exemplary operations for vehicle configuration determination for vehicle navigation, in accordance with an embodiment of the disclosure. FIG. 3 is explained in conjunction with elements from FIG. 1 and FIG. 2. With reference to FIG. 3, there is shown the block diagram 300 that illustrates the first set of exemplary operations from 302 to 324, as described herein. The first set of exemplary operations illustrated in the block diagram 300 starts at 302 and are performed by any computing system, apparatus, or device, such as by the computer 102 of FIG. 1 or by the computer system 202 of FIG. 2. Although illustrated with discrete blocks, the first set of exemplary operations associated with one or more blocks of the block diagram 300 can be divided into additional blocks, combined into fewer blocks, or eliminated, depending on the implementation.

At 302, a vehicle data reception operation is executed. In the vehicle data reception operation, the computer system 202 receives the vehicle data 204A associated with the set of vehicles 206 present on the road segment 210. The vehicle data 204A includes at least the speed of each vehicle of the set of vehicles 206 and the geographical location of each vehicle of the set of vehicles 206. The vehicle data 204A further includes, by way of example, and not by limitation, the heading direction of each vehicle of the set of vehicles 206. In an embodiment of the disclosure, the computer system 202 utilizes vehicle-to-vehicle (V2V) communication to receive the vehicle data 204A from the one or more data sources 204. The V2V communication is a wireless technology that enables each vehicle of the set of vehicles 206 to exchange real-time information regarding the speed, position, and status to enhance road safety and traffic efficiency through direct communication protocols, such as dedicated short-range communication (DSRC).

By way of example, and not by limitation, the vehicle data 204A indicates that vehicles A, B, C, D, and E are present on the road segment. The speed of vehicles A, B, C, D, and E are 30 km/h, 35 km/h, 50 km/h, 40 km/h, and 25 km/h respectively. The geographical coordinates of the vehicle A are “Latitude: 37.7755° N, Longitude: −122.4180° W”. The heading direction of vehicle A is ‘66.8 degrees’ indicating that the vehicle A is traveling in a direction that is slightly east of northeast.

At 304, an infrastructure connectivity data reception operation is executed. In the infrastructure connectivity data reception operation, the computer system 202 receives the infrastructure connectivity data 204B associated with one or more infrastructures 212 present on the road segment 210. In an embodiment of the disclosure, the computer system 202 utilizes vehicle-to-everything (V2X) communication to receive the infrastructure connectivity data 204B from the one or more data sources 204. The V2X communication is a wireless technology that enables the set of vehicles 206 to interact with various entities, including the one or more infrastructures 212, to enhance traffic management through real-time data exchange through direct communication protocols, such as the DSRC. The V2X communication includes, by way of example, and not by example, the V2V communication, and vehicle-to-infrastructure (V2I) communication. The V2I communication is a wireless technology that enables the one or more infrastructures 212 to interact with various entities, including the set of vehicles 206, to enhance traffic management through real-time data exchange through direct communication protocols, such as the DSRC. The infrastructure connectivity data 204B includes, by way of example, and not by limitation, the geographical location of each infrastructure of the one or more infrastructures 212. Each infrastructure of the one or more infrastructures 212 includes at least the spatial mapping sensor 212A.

By way of example, and not by limitation, the infrastructure connectivity data 204B includes that infrastructures A, B, and C are present on the road segment 210. The geographical coordinates of the infrastructures A, B, and C are “Latitude: 34.0522° N, Longitude: −118.2437° W”, “Latitude: 34.0525° N, Longitude: −118.2450° W”, and “Latitude: 34.0530° N, Longitude: −118.2465° W” respectively.

In various embodiments of the disclosure, the infrastructure connectivity data 204B further includes at least the speed of each vehicle of the set of vehicles 206 and the geographical location of each vehicle of the set of vehicles 206. In various embodiments of the disclosure, the infrastructure connectivity data 204B includes the atmospheric data including, by way of example, and not by limitation, the presence of dust in the environment of the road segment 210, the humidity level in the environment of the road segment 210, the pressure of air in the environment of the road segment 210, the temperature value of the environment of the road segment 210, the presence of precipitation across the road segment 210, the visibility across the road segment 210, and the wind speed associated with the road segment 210.

At 306, a map data reception operation is executed. In the map data reception operation, the computer system 202 receives the map data 204C associated with the road segment 210. In an embodiment of the disclosure, the computer system 202 receives the map data 204C from the map database associated with the one or more data sources 204.

The map data 204C includes, by way of example, and not by limitation, the geographical location of the one or more traffic signals present on the road segment 210, the status of each traffic signal of the one or more traffic signals, the surface quality of the road segment 210, the status of traffic present on the road segment 210, the maximum allowable speed limit for the road segment 210, the width of the road segment 210, the set of lanes within the road segment 210, the width of each lane of the set of lanes, and the presence of a physical divider within the road segment 210.

By way of example, and not by limitation, the map data 204C includes the geographical location of a traffic signal indicative of “40.7128° N, Longitude: −74.0060° W”. The status of the traffic signal indicates ‘STOP’. The surface quality of the road segment 210 indicates an International Roughness Index (IRI) of 2.5 m/km. The maximum allowable speed limit for the road segment 210 is ‘60 km/h’. The width of the road segment is ‘13 meters’ which includes 4 lanes (2 lanes for northbound traffic and 2 lanes for southbound traffic) each of width 3 meters. A concrete divider of width 1 meter is present between the northbound and southbound lanes of the road segment 210.

At 308, a model application operation is executed. In the model application operation, the computer system 202 applies the ML model 214 to the vehicle data 204A, the infrastructure connectivity data 204B, and the map data 204C. The ML model 214 corresponds to the computational network or the system of artificial neurons, arranged in the plurality of layers, as the nodes. In an embodiment of the disclosure, the output of the ML model 214 for an input is utilized to determine the set of vehicle configurations 216 associated with the set of vehicles 206. The input includes at least the vehicle data 204A, the infrastructure connectivity data 204B, and the map data 204C. Details about the determination of the set of vehicle configurations 216 are provided at 310.

In various embodiments of the disclosure, the computer system 202 determines an atmospheric value based on the application of the ML model 214 to the vehicle data 204A, the infrastructure connectivity data 204B, and the map data 204C. The atmospheric value is a measure of an alteration of radiant energy as the radiant energy passes through the atmosphere. By way of example, and not by limitation, the atmospheric value corresponds to a measure of how much sunlight is reduced as the sunlight passes through the atmosphere. In the case of a clear day (e.g., a sunny day with no or little clouds in the atmosphere), the atmospheric value is low (e.g., 0.85) indicating that 85% of incoming solar radiation reaches the surface of the road segment 210. In case of a hazy or polluted day, the atmospheric value is higher (e.g., 0.5) indicating that 50% of the incoming solar radiation reaches the surface of the road segment 210, which leads to scattering of the incoming solar radiation due to atmospheric particles and pollutants. In an embodiment of the disclosure, a first set of power values is obtained based on the atmospheric value. A supply of power to the set of sensors of at least the first vehicle 206A of the set of vehicles 206 is controlled based on the first set of power values. The set of sensors of the first vehicle 206A includes at least the specific spatial mapping sensor 208. By way of example, and not by limitation, the power value associated with the specific spatial mapping sensor 208 of the first vehicle 206A is obtained based on the atmospheric value. The power value for the specific spatial mapping sensor 208 of the first vehicle 206A will be higher at the atmospheric value ‘0.5’ as compared to the power value for the specific spatial mapping sensor 208 of the first vehicle at the atmospheric value ‘0.85’. Details about the utilization of the first set of power values are provided at 318 in FIG. 3.

In an alternate embodiment of the disclosure, the ML model 214 utilizes a first input to determine the atmospheric value. The first input includes, by way of example, and not by limitation, a power value of signal transmitted from the spatial mapping sensor of each vehicle of the set of vehicles 206, a power value of signal received (the transmitted signal that is reflected from one or more objects present in the environment of the road segment 210) by the spatial mapping sensor of each vehicle of the set of vehicles 206, historical infrastructure data, historical vehicle data, and the atmospheric data. The historical infrastructure data corresponds to a collection of records of, by way of example, and not by limitation, the presence of buildings in the vicinity of the road segment 210, the presence of trees in the vicinity of the road segment 210, the presence of bridges in the vicinity of the road segment 210, and presence of industrial facilities (e.g., solar panel construction facility) in the vicinity of the road segment 210. The historical vehicle data corresponds to a collection of records of, by way of example, and not by limitation, traffic congestion associated with the road segment 210, and traffic patterns (e.g., increased vehicle movement during working hours) associated with the road segment 210.

In various embodiments of the disclosure, the computer system 202 utilizes historical atmospheric data to determine the atmospheric value. The historical atmospheric data corresponds to a collection of records of, by way of example, and not by limitation, the atmospheric data captured by the set of sensors of the one or more infrastructures 212, the atmospheric data captured by the set of sensors of at least the first vehicle 206A of the set of vehicles 206, the power of the signal transmitted by the spatial mapping sensor of at least the first vehicle 206A, the power of the signal received by the spatial mapping sensor of at least the first vehicle 206A, and weather information stored in the one or more data sources 204. The computer system 202 applies the ML model 214 to the historical atmospheric data to determine the atmospheric value.

At 310, a configuration determination operation is executed. In the configuration determination operation, the computer system 202 determines the set of vehicle configurations 216 associated with the set of vehicles 206 based on the application of the ML model 214 to the vehicle data 204A, the infrastructure connectivity data 204B, and the map data 204C. Each vehicle configuration of the set of vehicle configurations 216 indicates the arrangement of the set of vehicles 206 on the road segment 210.

By way of example, and not by limitation, the set of vehicles 206 includes the vehicles M, N, and O present on the road segment 210 which includes lanes A and B. The set of vehicle configurations 216 includes vehicle configurations (Vehicle-Lane), “M-A, N-A, O-A” (vehicle M is present ahead of the vehicle N, and vehicle N is present ahead of the vehicle O), “M-A, N-A, O-A” (vehicle M is present ahead of the vehicle O, and vehicle O is present ahead of the vehicle N), “M-A, N-A, O-A” (vehicle N is present ahead of the vehicle M, and vehicle M is present ahead of the vehicle O), “M-A, N-A, O-A” (vehicle O is present ahead of the vehicle M, and vehicle M is present ahead of the vehicle N), “M-A, N-A, O-A” (vehicle N is present ahead of the vehicle O, and vehicle O is present ahead of the vehicle M), “M-A, N-A, O-A” (vehicle O is present ahead of the vehicle N, and vehicle N is present ahead of the vehicle M), “M-A, N-A, O-B” (vehicle M is present ahead of the vehicle N), “M-A, N-A, O-B” (vehicle N is present ahead of the vehicle M), “M-A, N-B, O-A” (vehicle M is present ahead of the vehicle O), “M-A, N-B, O-A” (vehicle O is present ahead of the vehicle M), “M-B, N-A, O-A” (vehicle N is present ahead of the vehicle O), “M-B, N-A, O-A” (vehicle O is present ahead of the vehicle N), “M-A, N-B, O-B” (vehicle O is present ahead of the vehicle N), “M-A, N-B, O-B” (vehicle N is present ahead of the vehicle O), “M-B, N-A, O-B” (vehicle M is present ahead of the vehicle N), “M-B, N-A, O-B” (vehicle N is present ahead of the vehicle M), “M-A, N-B, O-B” (vehicle N is present ahead of the vehicle O), “M-A, N-B, O-B” (vehicle O is present ahead of the vehicle N), “M-B, N-B, O-B” (vehicle M is present ahead of the vehicle N, and vehicle N is present ahead of the vehicle O), “M-B, N-B, O-B” (vehicle M is present ahead of the vehicle O, and vehicle O is present ahead of the vehicle N), “M-B, N-B, O-B” (vehicle N is present ahead of the vehicle M, and vehicle M is present ahead of the vehicle O), “M-B, N-B O-B” (vehicle O is present ahead of the vehicle M, and vehicle M is present ahead of the vehicle N), “M-B, N-B, O-B” (vehicle N is present ahead of the vehicle O, and vehicle O is present ahead of the vehicle M), and “M-B, N-B, O-B” (vehicle O is present ahead of the vehicle N, and vehicle N is present ahead of the vehicle M).

In various embodiments of the disclosure, the computer system 202 generates the virtual representation of the set of vehicle configurations 216 based on the application of the ML model 214 to the vehicle data 204A, the infrastructure connectivity data 204B, and the map data 204C. The computer system 202 further simulates the virtual representation of the set of vehicle configurations 216 based on the one or more criteria 218. The one or more criteria 218 includes at least one of the power consumption by the spatial mapping sensor of each vehicle of the set of vehicles 206, the driving range of each vehicle of the set of vehicles 206, or the travel route of each vehicle of the set of vehicles 206. The computer system 202 simulates the virtual representation of the set of vehicle configurations 216 by simulating different arrangements of the set of vehicles 206 present on the road segment 210 in a virtual representation of the road segment 210. The computer system 202 simulates the virtual representation of the set of vehicle configurations 216 to select the vehicle configuration 216A from the set of vehicle configurations 216. Details about the generation and simulation of the set of vehicle configurations 216 are provided, in FIG. 4, and its corresponding description.

At 312, a configuration selection operation is executed. In the configuration selection operation, the computer system 202 selects the vehicle configuration 216A from the set of vehicle configurations 216 based on the one or more criteria 218. The one or more criteria 218 includes at least one of the power consumption by the spatial mapping sensor of each vehicle of the set of vehicles 206, the driving range of each vehicle of the set of vehicles 206, or the travel route of each vehicle of the set of vehicles 206.

By way of example, and not by limitation, the set of vehicles 206 includes three identical vehicles M, N, and O present on the road segment 210 which includes lanes A and B. The set of vehicle configurations 216 includes vehicle configurations (Vehicle-Lane), “M-A, N-A, O-A”, “M-A, N-A, O-B”, “M-A, N-B, O-A”, “M-B, N-A, O-A”, “M-A, N-B, O-B”, “M-B, N-A, O-B”, “M-A, N-B, O-B”, and “M-B, N-B, O-B”. The first set of power values includes the power value for the spatial mapping sensor of the vehicle M, the power value for the spatial mapping sensor of the vehicle N, and the power value for the spatial mapping sensor of the vehicle O. The first set of power values associated with each vehicle configuration of the set of vehicle configurations 216 is 45 watts, 36 watts, 30 watts, 34 watts, 39 watts, 48 watts, 42 watts, and 38 watts respectively. The computer system 202 selects the vehicle configuration 216A “M-A, N-A, O-B” based on the one or more criteria 218. The first set of power values associated with the vehicle configuration 216A “M-A, N-A, O-B” is 36 watts. The computer system 202 selects the vehicle configuration 216A based on the one or more criteria 218 including at least one of the power consumption by the spatial mapping sensor of the vehicle M, the spatial mapping sensor of the vehicle N, the spatial mapping sensor of the vehicle O, the driving range of the vehicle M, the driving range of the vehicle N, the driving range of the vehicle O, the travel route of the vehicle M, the travel route of the vehicle N, or the travel route of the vehicle O.

For instance, in the selection of the vehicle configuration 216A “M-A, N-A, O-B”, the minimum value of the first set of power values is associated with the vehicle configuration “M-A, N-B, O-A” (30 watts). However, the vehicle N may navigate in the lane A to reach the final destination associated with the vehicle N, and the vehicle O may navigate in the lane B to reach the final destination associated with the vehicle O. Therefore, the computer system 202 selects the vehicle configuration 216A “M-A, N-A, O-B” based on the one or more criteria 218.

In an embodiment of the disclosure, the computer system 202 selects the vehicle configuration 216A from the set of vehicle configurations 216 based on a result of the simulation of the virtual representation of the set of vehicle configurations 216. Details about selecting the vehicle configuration 216A from the set of vehicle configurations 216 based on the result of the simulation of the virtual representation of the set of vehicle configurations 216 are provided, in FIG. 4, and its corresponding description.

At 314, a vehicle control operation is executed. In the vehicle control operation, the computer system 202 controls at least the first vehicle 206A of the set of vehicles 206 based on the vehicle configuration 216A. In an embodiment of the disclosure, the computer system 202 controls at least the first vehicle 206A of the set of vehicles 206 by rearranging the position of the at least the first vehicle 206A of the set of vehicles 206 on the road segment 210 to reduce the power consumption by the set of vehicles 206. In various embodiments of the disclosure, the computer system 202 controls at least the first vehicle 206A of the set of vehicles 206 to improve the power consumption by the spatial mapping sensor of each vehicle of the set of vehicles 206. The improvement in the power consumption by the spatial mapping sensor of each vehicle of the set of vehicles 206 further improves the driving range of each vehicle of the set of vehicles 206. By way of example, and not by limitation, the first vehicle 206A is navigating behind the second vehicle 206B. The specific spatial mapping sensor 208 of the first vehicle 206A consumes 15 watts of power to capture the area of the road segment 210 as the second vehicle 206B is obstructing the field of view of the specific spatial mapping sensor 208 of the first vehicle 206A. The computer system 202 controls the first vehicle 206A by increasing the speed of the first vehicle 206A and positions the first vehicle in the lane adjacent to the lane in which the second vehicle 206B is navigating. The specific spatial mapping sensor 208 of the first vehicle now consumes 12 watts of power to capture the area of the road segment 210 as the second vehicle 206B no more obstructs the field of view of the specific spatial mapping sensor 208 of the first vehicle 206A.

The control of at least the first vehicle 206A of the set of vehicles 206 corresponds to, by way of example, and not by limitation, increase in the speed of at least the first vehicle 206A of the set of vehicles 206, decrease in the speed of at least the first vehicle 206A of the set of vehicles 206, maintaining a constant speed of at least the first vehicle 206A of the set of vehicles 206, changing lanes of at least the first vehicle 206A of the set of vehicles 206, and maintaining the same lane for at least the first vehicle 206A of the set of vehicles 206. By way of example, and not by limitation, the first vehicle 206A is navigating behind the second vehicle 206B. The computer system 202 controls the first vehicle 206A to position the first vehicle 206A beside the second vehicle 206B by increasing the speed of the first vehicle 206A. The specific spatial mapping sensor 208 of the first vehicle 206A consumes less power while present beside the second vehicle 206B as compared to the first vehicle present behind the second vehicle 206B. By way of example, and not by limitation, the first vehicle 206A is navigating behind the second vehicle 206B at a distance less than a defined distance between the first vehicle 206A and the second vehicle 206B. The computer system 202 controls the first vehicle 206A to position the first vehicle 206A behind the second vehicle 206B at a distance greater than the defined distance between the first vehicle 206A and the second vehicle 206B by decreasing the speed of the first vehicle 206A. The specific spatial mapping sensor 208 of the first vehicle 206A consumes less power while present at a distance greater than the defined distance between the first vehicle 206A and the second vehicle 206B as compared to the distance less than the defined distance between the first vehicle 206A and the second vehicle 206B.

By way of example, and not by limitation, the first vehicle 206A is navigating behind the second vehicle 206B at a distance equal to the defined distance between the first vehicle 206A and the second vehicle 206B. The computer system 202 controls the first vehicle 206A to position the first vehicle 206A behind the second vehicle 206B at a distance equal to the defined distance between the first vehicle 206A and the second vehicle 206B by maintaining the speed of the first vehicle 206A. The specific spatial mapping sensor 208 of the first vehicle 206A consumes less power while present at a distance equal to the defined distance between the first vehicle 206A and the second vehicle 206B as compared to the distance less than or greater than the defined distance between the first vehicle 206A and the second vehicle 206B.

By way of example, and not by limitation, the first vehicle 206A is navigating behind the second vehicle 206B in the lane A. The computer system 202 controls the first vehicle 206A to position the first vehicle 206A in the lane B. The specific spatial mapping sensor 208 of the first vehicle 206A consumes less power while present in lane B as navigating in the lane B improves the field of view of the specific spatial mapping sensor 208 of the first vehicle 206A. By way of example, and not by limitation, the first vehicle 206A is navigating behind the second vehicle 206B in the lane A. The computer system 202 controls the first vehicle 206A to maintain the navigation of the first vehicle 206A in the lane A. The specific spatial mapping sensor 208 of the first vehicle 206A consumes less power while maintaining the navigation in the lane A rather than changing the path to lane B. The field of view of the specific spatial mapping sensor 208 of the first vehicle 206A is better in lane A as compared to the field of view of the specific spatial mapping sensor 208 of the first vehicle 206A in lane B.

At 316, a first power acquisition operation is executed. In the first power acquisition operation, the computer system 202 obtains the first set of power values based on the vehicle configuration 216A. The first set of power values is associated with the set of sensors of at least the first vehicle 206A of the set of vehicles 206. The set of sensors includes at least the spatial mapping sensor. The first set of power values includes power values at which the power is supplied to the set of sensors of at least the first vehicle 206A of the set of vehicles 206. The first set of power values is vital to control the supply of the power to the set of sensors of at least the first vehicle 206A of the set of vehicles 206. The supply of power to the set of sensors of the first vehicle 206A is controlled from the battery of the first vehicle 206A. By way of example, and not by limitation, the first set of power values includes power values at which the computer system 202 controls the supply of power to the spatial mapping sensor of at least the first vehicle 206A of the set of vehicles 206. In an embodiment of the disclosure, the computer system 202 obtains the first set of power values based on the atmospheric value associated with the vehicle configuration 216A. Details about determining the atmospheric value are provided, at 308 in FIG. 3.

By way of example, and not by limitation, the first set of power values includes a first subset of power values associated with the first vehicle 206A. The first subset of power values includes a power value for the specific spatial mapping sensor 208 of the first vehicle 206A, a power value for a global positioning sensor (GPS) of the first vehicle 206A, and a power value for an accelerometer of the first vehicle 206A.

At 318, a first power control operation is executed. In the first power control operation, the computer system 202 controls the supply of power to the set of sensors of at least the first vehicle 206A of the set of vehicles 206 based on the first set of power values from the battery of the first vehicle 206A. In an embodiment of the disclosure, the computer system 202 controls the supply of electrical energy to the set of sensors of at least the first vehicle 206A of the set of vehicles 206 based on the first set of power values. The power to each sensor of the set of sensors of at least the first vehicle 206A of the set of vehicles 206 is supplied at the first set of power values.

By way of example, and not by limitation, the first subset of power values includes the power value for the specific spatial mapping sensor 208 of the first vehicle 206A (e.g., 15 watts), the power value for the GPS of the first vehicle 206A (e.g., 0.5 watts), and the power value for the accelerometer of the first vehicle 206A (e.g., 0.05 watts). The computer system 202 controls the supply of the power to the specific spatial mapping sensor 208 of the first vehicle 206A at 15 watts. The computer system 202 controls the supply of power to the GPS of the first vehicle 206A at 0.5 watts. The computer system 202 controls the supply of power to the accelerometer of the first vehicle 206A at 0.05 watts.

In various embodiments of the disclosure, the computer system 202 controls the intensity of light emitted by at least one light emitting device associated with at least the first vehicle 206A of the set of vehicles 206. The computer system 202 applies the ML model 214 to the atmospheric data to determine a set of vehicle illuminance values. Each vehicle illuminance value of the set of vehicle illuminance values is indicative of an intensity of the light emitted by the at least one light emitting device associated with at least the first vehicle 206A of the set of vehicles 206. The computer system 202 controls the intensity of light emitted by at least one light emitting device associated with at least the first vehicle 206A of the set of vehicles 206 based on the set of vehicle illuminance values. The control of the intensity of light emitted by the at least one light emitting device associated with at least the first vehicle 206A of the set of vehicles 206 improves the consumption of energy by the at least one light emitting device associated with at least the first vehicle 206A of the set of vehicles 206 by emitting the light with an intensity that is vital for the navigation of at least the first vehicle 206A of the set of vehicles 206. As excessive intensity of light is not emitted by the at least one light emitting device, the battery of at least the first vehicle 206A is preserved. The preserved battery further improves the range of at least the first vehicle 206A.

By way of example, and not by limitation, the first vehicle 206A includes a first light emitting device and a second light emitting device. The computer system 202 controls the power supplied to the first light emitting device, and the second light emitting device based on the set of vehicle illuminance values. The set of vehicle illuminance values includes an intensity of 700 lumens for the first light emitting device and an intensity of 800 lumens for the second light emitting device.

At 320, a second power acquisition operation is executed. In the second power acquisition operation, the computer system 202 obtains a second set of power values based on the vehicle configuration 216A. The second set of power values is associated with the set of sensors of the at least one infrastructure of the one or more infrastructures 212. The set of sensors of the at least one infrastructure of the one or more infrastructures 212 includes at least the spatial mapping sensor 212A. The second set of power values includes power values at which the power is supplied to the set of sensors of the at least one infrastructure of the one or more infrastructures 212. The second set of power values is vital to control the supply of the power to the set of sensors of the at least one infrastructure of the one or more infrastructures 212. The supply of power to the set of sensors of the one or more infrastructures 212 is controlled from a power grid. By way of example, and not by limitation, the first set of power values includes power values at which the computer system 202 controls the supply of power to the spatial mapping sensor 212A of the at least one infrastructure of the one or more infrastructures 212. In an embodiment of the disclosure, the computer system 202 obtains the second set of power values based on the atmospheric value associated with the vehicle configuration 216A. Details about determining the atmospheric value are provided, at 308 in FIG. 3.

By way of example, and not by limitation, the second set of power values includes a second subset of power values associated with a first infrastructure of the one or more infrastructures 212. The second subset of power values includes a power value for the spatial mapping sensor 212A of the first infrastructure.

At 322, a power transmission operation is executed. In the power transmission operation, the computer system 202 transmits the second set of power values to the set of sensors associated with at least one infrastructure of the one or more infrastructures 212. By way of example, and not by limitation, the computer system 202 utilizes the V2I communication to transmit the second set of power values to the set of sensors associated with at least one infrastructure of the one or more infrastructures 212.

At 324, a second power control operation is executed. In the second power control operation, the computer system 202 controls the supply of power to the set of sensors of the at least one infrastructure of the one or more infrastructures 212 based on the transmitted second set of power values from the power grid. In an embodiment of the disclosure, the computer system 202 controls the supply of electrical energy to the set of sensors of the at least one infrastructure of the one or more infrastructures 212 based on the transmitted second set of power values. The power to each sensor of the set of sensors of the at least one infrastructure of the one or more infrastructures 212 is supplied at the second set of power values. By way of example, and not by limitation, the first subset of power values includes the power value for the spatial mapping sensor 212A of the first infrastructure of the one or more infrastructures 212 (e.g., 20 watts). The computer system 202 controls the supply of the power to the spatial mapping sensor 212A of the first infrastructure at 20 watts.

In various embodiments of the disclosure, the computer system 202 controls the intensity of light emitted by one or more light emitting devices associated with the at least one infrastructure of the one or more infrastructures 212. The computer system 202 applies the ML model 214 to the atmospheric data to determine a set of infrastructure illuminance values. Each infrastructure illuminance value of the set of infrastructure illuminance values is indicative of the intensity of the light emitted by the one or more light-emitting devices associated with the at least one infrastructure of the one or more infrastructures 212. The computer system 202 controls the intensity of light emitted by the one or more light emitting devices associated with the at least one infrastructure of the one or more infrastructures 212 based on the set of infrastructure illuminance values. The control of the intensity of light emitted by the one or more light emitting devices associated with the at least one infrastructure of the one or more infrastructures 212 improves the consumption of energy by the at least one light emitting device associated with at least the first vehicle 206A of the set of vehicles 206 by increasing the intensity of the light emitted by the one or more light emitting devices associated with the at least one infrastructure of the one or more infrastructures 212 for the navigation of at least the first vehicle 206A of the set of vehicles 206. The illumination of the road segment 210 by the one or more light emitting devices associated with the at least one infrastructure of the one or more infrastructures 212 reduces the dependency on usage of the at least one light emitting device of at least the first vehicle 206A which further preserves the battery of at least the first vehicle 206A. The preserved battery further improves the range of at least the first vehicle 206A.

By way of example, and not by limitation, the first infrastructure includes a third light emitting device and a fourth light emitting device. The computer system 202 controls the power supplied to the third light emitting device, and the fourth light emitting device based on the set of infrastructure illuminance values. The set of infrastructure illuminance values includes an intensity of 900 lumens for the third light emitting device and an intensity of 1000 lumens for the fourth light emitting device.

In various embodiments of the disclosure, the computer system 202 calculates a signal noise value associated with the environment of the road segment 210 based on the vehicle configuration 216A. The signal noise value is indicative of a ratio of the power of a signal (e.g., a laser signal reflected from one or more objects present on the road segment 210) received by the spatial mapping sensor of a vehicle (e.g., the first vehicle 206A) to a power of a background noise associated with the environment of the road segment 210. The background noise corresponds to an interference present in the environment of the road segment 210 that may distort the signal received by the specific spatial mapping sensor 208 of the first vehicle 206A. Sources of the background noise include, by way of example, and not by limitation, light emitting devices associated with the at least one infrastructure of the one or more infrastructures 212, light emitting devices associated with at least the first vehicle 206A of the set of vehicles 206, wind resistance, dust, fog, rain, and humidity. The computer system 202 utilizes the below-mentioned equation to calculate the signal noise value:

$$r = \frac{{P}_{r} * {S}_{λ} * M}{\sqrt{2 * e * B * [ ( {P}_{r} + {P}_{B} ) * {S}_{λ} + {I}_{D} ] * F * {M}^{2} + \frac{4 * k * T * B}{{R}_{O}}}}$$

Where,
r is the signal noise value,
Pᵣ is indicative of the power of the signal received by the spatial power sensor,
S_{λ} is indicative of the sensitivity of the detector of the spatial mapping sensor in detecting the signal received by the spatial mapping sensor,
M is indicative of a value associated with an amplification by the detector to amplify the signal received by the spatial mapping sensor,
e is indicative of an elementary charge associated with the spatial mapping sensor,
B is indicative of a bandwidth (or range of frequencies) associated with the detector of the spatial mapping sensor at which the detector may measure the signal received by the spatial mapping sensor,
P_{B} is indicative of an average power associated with the background noise,
I_{D} is indicative of a dark current associated with the spatial mapping sensor. The dark current is indicative of an unwanted electric current that flows through the spatial mapping sensor,
F is indicative of a noise factor associated with the spatial mapping sensor. The noise factor indicates a value of noise that is added by the spatial mapping sensor to the received signal,
k is indicative of the Boltzmann constant,
T is indicative of a temperature value associated with the environment of the road segment 210,
B is indicative of a bandwidth associated with the detector of the spatial mapping sensor,
R₀ is indicative of the resistance of a load present in the spatial mapping sensor.

By way of example, and not by limitation, the signal noise value is ‘5’ for the intensity of light emitted by one or more light emitting devices associated with the at least one infrastructure of the one or more infrastructures 212 indicative of 300 watts per square meters. The computer system 202 obtains the set of infrastructure illuminance values associated with the vehicle configuration 216A. The computer system 202 controls the one or more light emitting devices associated with the at least one infrastructure of the one or more infrastructures 212 based on the set of infrastructure illuminance values. Now, the intensity of light emitted by one or more light emitting devices associated with the at least one infrastructure of the one or more infrastructures 212 is 100 watts per square meter. Now, the signal noise value is ‘15’, which improves the power consumption by the one or more light emitting devices and further reduces distortion of the signal received by the spatial mapping sensor of the first vehicle 206A.

FIG. 4 is a diagram that illustrates exemplary operations for simulation of the set of vehicle configurations, in accordance with an embodiment of the disclosure. FIG. 4 is explained in conjunction with elements from FIG. 1, FIG. 2, and FIG. 3. With reference to FIG. 4, there is shown the block diagram 400 that illustrates the exemplary operations from 402 to 410, as described herein. The exemplary operations illustrated in the block diagram 400 start at 402 and are performed by any computing system, apparatus, or device, such as by the computer 102 of FIG. 1 or by the computer system 202 of FIG. 2. Although illustrated with discrete blocks, the exemplary operations associated with one or more blocks of the block diagram 400 can be divided into additional blocks, combined into fewer blocks, or eliminated, depending on the implementation.

At 402, the model application operation is executed. In the model application operation, the computer system 202 applies the ML model 214 to the vehicle data 204A, the infrastructure connectivity data 204B, and the map data 204C. The ML model 214 corresponds to the computational network or the system of artificial neurons, arranged in the plurality of layers, as the nodes. In an embodiment of the disclosure, the output of the ML model 214 for the input is utilized to determine the set of vehicle configurations 216 associated with the set of vehicles 206. The input includes at least the vehicle data 204A, the infrastructure connectivity data 204B, and the map data 204C. Details about the vehicle data 204A, the infrastructure connectivity data 204B, and the map data 204C are provided, in FIG. 2.

At 404, a visual representation generation operation is executed. In the visual representation generation operation, the computer system 202 generates the virtual representation of the set of vehicle configurations 216 based on the application of the ML model 214 to the vehicle data 204A, the infrastructure connectivity data 204B, and the map data 204C. Each vehicle configuration of the set of vehicle configurations 216 corresponds to the arrangement of the set of vehicles 206 on the road segment 210. The virtual representation may be a digital twin of the set of vehicle configurations 216 that may be generated using the vehicle data 204A, the infrastructure connectivity data 204B, and the map data 204C. In the generation of the virtual representation of the set of vehicle configurations 216, the computer system 202 may be configured to utilize stored environmental knowledge associated with the environment of the road segment 210 to generate the virtual representation of the set of vehicle configurations 216. The stored environmental knowledge stored in the one or more data sources 204 includes at least the vehicle data 204A, the infrastructure connectivity data 204B, and the map data 204Csegment 210segment 210. Further, the stored environmental knowledge may correspond to information about the surroundings of the environment of the road segment 210 or the context in which the set of vehicles 206 are navigating. The stored environmental knowledge may include details, such as the geographical location of infrastructures in the vicinity of the road segment 210, a layout of the environment of the road segment 210, and relevant factors that may impact how the set of vehicles 206 may navigate on the road segment 210, a position or an orientation of each vehicle of the set of vehicles 206 in the environment of the road segment 210. The computer system 202 further simulates the generated virtual representation of the set of vehicle configurations 216. Details about the simulation of the virtual representation of the set of vehicle configurations 216 are provided at 406, and its corresponding description.

At 406, a virtual representation simulation operation is executed. In the virtual representation simulation operation, the computer system 202 simulates the generated virtual representation of the set of vehicle configurations 216 based on the one or more criteria 218. The one or more criteria 218 include at least one of the power consumption by the spatial mapping sensor of each vehicle of the set of vehicles 206, the driving range of each vehicle of the set of vehicles 206, or the travel route of each vehicle of the set of vehicles 206. The power consumption by the spatial mapping sensor of each vehicle of the set of vehicles 206 is vital as, for example, the specific spatial mapping sensor 208 of the first vehicle 206A has the highest power consumption as compared to the spatial mapping sensor of any vehicle of the set of vehicles 206. Therefore, the computer system 202 simulates the set of vehicle configurations 216 such that the first vehicle 206A may be arranged in a way such that no vehicle may be navigating ahead of the first vehicle 206A up to a defined distance so that the power consumption by the specific spatial mapping sensor 208 of the first vehicle 206A may not increase due to reduction in the field of view of the specific spatial mapping sensor 208 of the first vehicle 206A.

The driving range of each vehicle of the set of vehicles 206 is vital as, for example, the available driving range of the first vehicle 206A is just enough for the first vehicle 206A to reach the destination of the first vehicle 206A. In case the first vehicle 206A is rearranged or navigated to a different lane on the road segment 210, the first vehicle 206A may not reach the destination. Therefore, the computer system 202 simulates the set of vehicle configurations 216 such that the first vehicle 206A is not rearranged.

The travel route of each vehicle of the set of vehicles 206 is vital as, for example, the first vehicle 206A needs to reach the destination of the first vehicle 206A in the minimum possible time duration. The first vehicle 206A is navigating through a travel route such that the first vehicle 206A may reach the destination in the minimum possible time. In case the first vehicle 206A is rearranged to a different lane on the road segment 210, the first vehicle 206A may have to take a different travel route which will increase the duration of the journey by ‘1.5 hours’. Therefore, the computer system 202 simulates the set of vehicle configurations 216 such that the first vehicle 206A is not rearranged.

In an embodiment of the disclosure, the computer system 202 simulates different arrangements of the set of vehicles present on the road segment 210 in a virtual representation of the road segment 210. In an embodiment of the disclosure, the computer system 202 runs different simulations on the set of vehicle configurations 216 to determine the power consumption by the spatial mapping sensor of each vehicle of the set of vehicles 206, the speed of each vehicle of the set of vehicles 206, and potential incidents that may arise with rearrangement of at least the first vehicle 206A of the set of vehicles 206 (e.g., changing the first vehicle 206A from lane A to lane B may lead to decrease in the range of the first vehicle 206A that may pose a challenge for the first vehicle 206A to reach the destination of the first vehicle 206A).

The computer system 202 utilizes the map data 204C associated with the road segment 210 to generate a digital representation of the environment of the road segment 210. The computer system 202 further generates the virtual representation of each vehicle of the set of vehicles 206 that may represent, by way of example, and not by limitation, spatial coordinates of each vehicle of the set of vehicles 206 indicating an exact location of each vehicle of the set of vehicles 206 in three-dimensional space, a heading direction of each vehicle of the set of vehicles 206, distance between any two vehicles of the set of vehicles 206, dimensions of each vehicle of the set of vehicles 206 (e.g., length of each vehicle of the set of vehicles 206, and width of each vehicle of the set of vehicles 206).

The computer system 202 further utilizes a simulation logic to replicate an actual arrangement of each vehicle of the set of vehicles 206 in the digital representation of the environment of the road segment 210. The simulation logic refers to a set of rules that govern the behavior and interactions of the set of vehicles 206 within the digital representation of the environment of the road segment 210. In an embodiment of the disclosure, the computer system 202 incorporates real-life characteristics (e.g., inclination of the road segment 210, friction associated with the surface of the road segment 210) to improve accuracy and similarity between the real-life configuration of the set of vehicles 206 and simulation of the configuration of the set of vehicles 206.

In an embodiment of the disclosure, the computer system 202 may utilize a plurality of factors to simulate the virtual representation of the set of vehicle configurations 216. The plurality of factors include, by way of example, and not by limitation, power rating of the spatial mapping sensor of each vehicle of the set of vehicles 206, physical dimensions of each vehicle of the set of vehicles 206 (e.g., the length of each vehicle of the set of vehicles 206, the width of each vehicle of the set of vehicles 206, the height of each vehicle of the set of vehicles 206, and the wheelbase of each vehicle of the set of vehicles 206), a minimum gap to be maintained between any two vehicles of the set of vehicles 206, a speed of each vehicle of the set of vehicles 206, a count of vehicles in the set of vehicles 206, the atmospheric value, the signal noise value associated with the environment of the road segment 210, infrastructures 212, the spatial mapping sensor of each vehicle of the set of vehicles 206, acceleration of each vehicle of the set of vehicles 206, and the energy usage by one or more onboard systems (e.g., a music player, an air conditioner) of each vehicle of the set of vehicles 206. The simulation of the set of vehicle configurations 216 includes, by way of example, and not by limitation, changing the power supplied to the spatial mapping sensor 212A of the one or more infrastructures 212, changing the power supplied to the spatial mapping sensor 212A of at least the first vehicle 206A of the set of vehicles 206, changing of the speed of each vehicle of the set of vehicles 206, and changing of the arrangement of each vehicle of the set of vehicles 206 on the road segment 210.

At 408, a simulation result generation operation is executed. In the simulation result generation operation, the computer system 202 generates a simulation result 408A based on the simulation of the virtual representation of the set of vehicle configurations 216. The simulation result 408A includes a speed at which each vehicle of the set of vehicles 206 should navigate a lane in which each vehicle of the set of vehicles 206 should navigate, a space (or a distance) between any two vehicles of the set of vehicles 206, a heading direction of each vehicle of the set of vehicles 206, traffic congestion present on the road segment 210, and surface data associated with the road segment 210.

At 410, the configuration selection operation is executed. In the configuration selection operation, the computer system 202 selects the vehicle configuration 216A based on the simulation result 408A and the one or more criteria 218. In various embodiments of the disclosure, the computer system 202 selects the vehicle configuration 216A based on the simulation result 408A and the power consumption by the spatial mapping sensor of each vehicle of the set of vehicles 206. In various embodiments of the disclosure, the computer system 202 selects the vehicle configuration 216A based on the simulation result 408A and the driving range of each vehicle of the set of vehicles 206. In various embodiments of the disclosure, the computer system 202 selects the vehicle configuration 216A based on the simulation result 408A and the travel route of each vehicle of the set of vehicles 206.

By way of example, and not by limitation, the set of vehicles 206 includes two vehicles M and N present on the road segment 210 which includes lanes A and B. The set of vehicle configurations 216 includes vehicle configurations (Vehicle-Lane), “M-A, N-A” (the vehicle M is ahead of the vehicle N), “M-A, N-A” (the vehicle N is ahead of the vehicle M), “M-A, N-B”, “M-B, N-A”, “M-B, N-B” (the vehicle M is ahead of the vehicle N), and “M-B, N-B” (the vehicle N is ahead of the vehicle M). The first set of power values includes the power value for the spatial mapping sensor of the vehicle M and the power value for the spatial mapping sensor of the vehicle N. The first set of power values associated with each vehicle configuration of the set of vehicle configurations 216 is 30 watts, 24 watts, 22 watts, 20 watts, 26 watts, and 25 watts respectively. The computer system 202 selects the vehicle configuration 216A “M-A, N-B” based on the one or more criteria 218. The first set of power values associated with the vehicle configuration 216A “M-A, N-B” is 22 watts. The computer system 202 selects the vehicle configuration 216A based on the one or more criteria 218 including at least one of the power consumption by the spatial mapping sensor of the vehicle M, the power consumption by the spatial mapping sensor of the vehicle N, the driving range of the vehicle M, the driving range of the vehicle N, the travel route of the vehicle M, or the travel route of the vehicle N.

For instance, in the selection of the vehicle configuration 216A “M-B, N-A”, the minimum value of the first set of power values is associated with the vehicle configuration “M-B, N-A” (20 watts). However, the vehicle M may navigate in the lane A to reach the final destination associated with the vehicle M, and the vehicle N may navigate in the lane B to reach the final destination associated with the vehicle N. Therefore, the computer system 202 selects the vehicle configuration 216A “M-A, N-B” based on the one or more criteria 218.

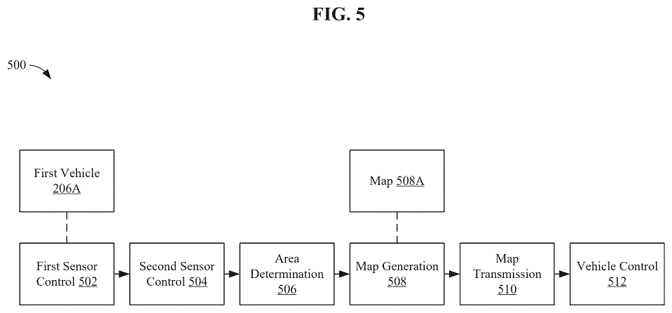

FIG. 5 is a diagram that illustrates exemplary operations for generation of a map based on geographical area, in accordance with an embodiment of the disclosure. FIG. 5 is explained in conjunction with elements from FIG. 1, FIG. 2, FIG. 3, and FIG. 4. With reference to FIG. 5, there is shown the block diagram 500 that illustrates the exemplary operations from 502 to 510, as described herein. The exemplary operations illustrated in the block diagram 500 start at 502 and are performed by any computing system, apparatus, or device, such as by the computer 102 of FIG. 1 or by the computer system 202 of FIG. 2. Although illustrated with discrete blocks, the exemplary operations associated with one or more blocks of the block diagram 500 can be divided into additional blocks, combined into fewer blocks, or eliminated, depending on the implementation.

At 502, a first sensor control operation is executed. In the first sensor control operation, the computer system 202 controls the set of sensors of the first vehicle 206A to capture a first geographical area. The set of sensors of the first vehicle 206A includes the spatial mapping sensor. The specific spatial mapping sensor 208 of the first vehicle 206A captures the first geographical area by emitting laser pulses into the environment of the road segment 210 and measuring the time taken by the laser pulses to reflect to the specific spatial mapping sensor 208 of the first vehicle 206A. Examples of set of sensors include, but are not limited to, LiDAR which utilizes laser pulses, RADAR which utilizes radio waves, visual cameras, and ultrasonic sensors which use sound waves. By way of example, and not by limitation, the computer system 202 controls an ultrasonic camera associated with the first vehicle 206A and the specific spatial mapping sensor 208 associated with the first vehicle 206A to capture the first geographical area.

The first geographical area refers to a defined spatial region characterized by the presence and configuration of transportation infrastructure, specifically roadways, highways, and associated features that ensure vehicular movement (e.g., the vehicular movement of the set of vehicles 206 on the road segment 210). The first geographical area encompasses the physical dimensions of the road network, including lanes, intersections, traffic control devices, and adjacent land uses, as well as the surrounding environment that influences traffic patterns, accessibility, and connectivity.

At 504, a second sensor control operation is executed. In the second sensor control operation, the computer system 202 controls at least one of the set of sensors of the second vehicle 206B of the set of vehicles 206 or the set of sensors of the at least one infrastructure of the one or more infrastructures 212 to capture a second geographical area. The set of sensors of the second vehicle 206B includes at least the spatial mapping sensor. The set of sensors of the at least one infrastructure of the one or more infrastructures 212 includes the spatial mapping sensor 212A. The spatial mapping sensor of the second vehicle 206B captures the second geographical area by emitting laser pulses into the environment of the road segment 210 and measuring the time taken by the laser pulses to reflect to the spatial mapping sensor of the second vehicle 206B. The spatial mapping sensor 212A of the at least one infrastructure of the one or more infrastructures 212 captures the second geographical area by emitting laser pulses into the environment of the road segment 210 and measuring the time taken by the laser pulses to reflect to the spatial mapping sensor 212A of the at least one infrastructure of the one or more infrastructures 212. Examples of set of sensors include, but are not limited to, LiDAR which utilizes laser pulses, RADAR which utilizes radio waves, visual cameras, and ultrasonic sensors which use sound waves. By way of example, and not by limitation, the computer system 202 controls the ultrasonic camera associated with the second vehicle 206B and the spatial mapping sensor associated with the second vehicle 206B to capture the second geographical area. By way of example, and not by limitation, the computer system 202 controls the spatial mapping sensor 212A of the first infrastructure of the one or more infrastructures 212 to capture the second geographical area.

In an embodiment of the disclosure, the first geographical area may be different from the second geographical area. By way of example, and not by limitation, the first vehicle 206A may be navigating behind the second vehicle 206B. The specific spatial mapping sensor 208 of the first vehicle 206A captures the first geographical area indicative of the area present in front of the first vehicle 206A and behind the second vehicle 206B. The spatial mapping sensor of the second vehicle 206B captures the second geographical area indicative of the area present in front of the second vehicle 206B.

By way of example, and not by limitation, the first vehicle 206A may be navigating across the road segment 210 such that the first vehicle is approaching towards the first infrastructure present on the road segment 210. The specific spatial mapping sensor 208 of the first vehicle 206A captures the first geographical area indicative of the area present in front of the first vehicle 206A and behind the first infrastructure. The spatial mapping sensor of the first infrastructure captures the second geographical area indicative of the area present in front of the first infrastructure.

At 506, an area determination operation is executed. In the area determination operation, the computer system 202 determines a third geographical area based on the first geographical area and the second geographical area. The third geographical area corresponds to a union of the first geographical area and the second geographical area. The computer system 202 further combines dissimilar portions of geographical areas among the first geographical area and the second geographical area to determine the third geographical area.

At 508, a map generation operation is executed. In the map generation operation, the computer system 202 generates a map 508A associated with the road segment 210 based on the third geographical area, the infrastructure connectivity data 204B, and the map data 204C. The map 508A indicates a virtual representation of the third geographical area. In an embodiment of the disclosure, the computer system 202 converts raw point cloud data captured by the specific spatial mapping sensor 208 of the first vehicle 206A, and the spatial mapping sensor of the second vehicle 206B into a structured, interpretable format that visually represents the topography, features, and characteristics of the third geographical area associated with the road segment 210 (e.g., the map 508A). In an alternate embodiment of the disclosure, the computer system 202 converts raw point cloud data captured by the specific spatial mapping sensor 208 of the first vehicle 206A, and the spatial mapping sensor 212A of the first infrastructure into a structured, interpretable format that visually represents the topography, features, and characteristics of the third geographical area associated with the road segment 210 (e.g., the map 508A).

In an embodiment of the disclosure, the map 508A is a detailed three-dimensional representation of the environment of the road segment 210. The map 508A includes precise measurements of obstacles and road features (e.g., lane markings) present within the road segment 210 as compared to conventional maps. The map 508A is dynamically updated in real-time which improves the safety of the set of vehicles 206 while navigating across the road segment 210.

At 510, a map transmission operation is executed. In the map transmission operation, the computer system 202 transmits the map 508A to at least the first vehicle 206A. By way of example, and not by limitation, the computer system 202 transmits the map 508A to the first vehicle 206A and the second vehicle 206B via V2V communication.

At 512, the vehicle control operation is executed. In the vehicle control operation, the computer system 202 controls the navigation of the first vehicle 206A through the road segment 210 based on the transmission of the map 508A to the first vehicle 206A. By way of example, and not by limitation, the computer system 202 controls the first vehicle 206A by navigating the first vehicle 206A from lane A of the road segment 210 to lane B of the road segment 210 by utilizing the map 508A.

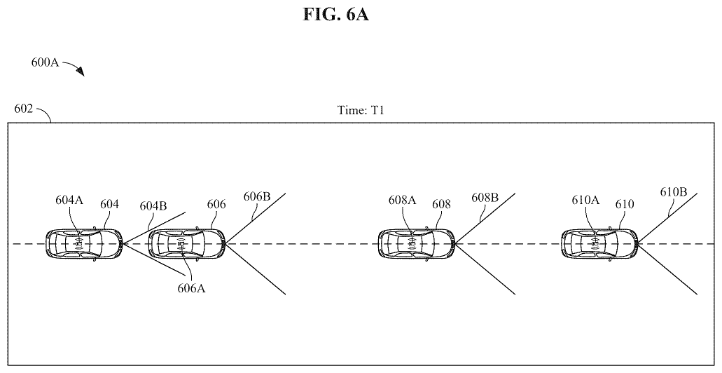

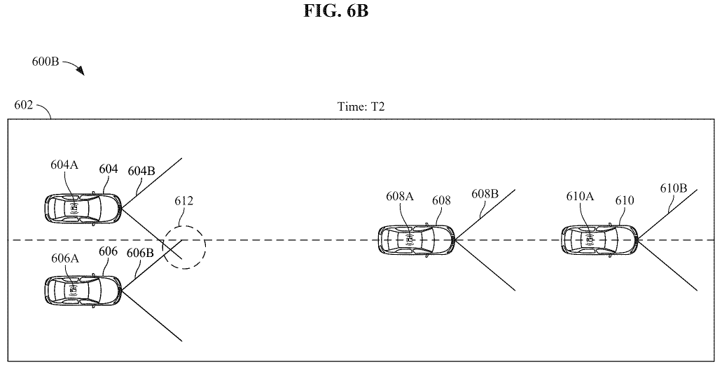

FIGS. 6A and 6B are diagrams that collectively illustrate an exemplary scenario for vehicle configuration determination for vehicle navigation, in accordance with an embodiment of the disclosure. FIGS. 6A and 6B are explained in conjunction with elements from FIGS. 1, 2, 3, 4, and 5. With reference to FIGS. 6A and 6B, there is shown an exemplary scenario 600 that includes a road segment 602, a first vehicle 604, a second vehicle 606, a third vehicle 608, a fourth vehicle 610, a spatial mapping sensor 604A of the first vehicle 604, a spatial mapping sensor 606A of the second vehicle 606, a spatial mapping sensor 608A of the third vehicle 608, a spatial mapping sensor 610A of the fourth vehicle 610, a first coverage range 604B captured by the spatial mapping sensor 604A of the first vehicle 604, a second coverage range 606B captured by the spatial mapping sensor 606A of the second vehicle 606, a third coverage range 608B captured by the spatial mapping sensor 608A of the third vehicle 608, and a fourth coverage range 610B captured by the spatial mapping sensor 610A of the fourth vehicle 610. The road segment 602 is an exemplary embodiment of the road segment 210 of FIG. 2. The first vehicle 604 is an exemplary embodiment of the first vehicle 206A of FIG. 2. The second vehicle 606 is an exemplary embodiment of the second vehicle 206B of FIG. 2. FIG. 6A may represent a scenario at a time “T1”. FIG. 6B may represent a scenario at time “T2” (after time “T1”).

With reference to FIG. 6A, the computer system 202 receives the vehicle data 204A associated with the first vehicle 604, the second vehicle 606, the third vehicle 608, and the fourth vehicle 610 present on the road segment 602. The computer system 202 further receives the infrastructure connectivity data 204B and the map data 204C from the one or more data sources 204. The computer system 202 applies the ML model 214 to the vehicle data 204A, the infrastructure connectivity data 204B, and the map data 204C. The computer system 202 determines the set of vehicle configurations 216 based on the application of the ML model 214. The set of vehicle configurations 216 is associated with the first vehicle 604, the second vehicle 606, the third vehicle 608, and the fourth vehicle 610. Each vehicle configuration of the set of vehicle configurations indicates an arrangement of the first vehicle 604, the second vehicle 606, the third vehicle 608, and the fourth vehicle 610 on the road segment 210. The computer system 202 further selects the vehicle configuration 216A from the set of vehicle configurations 216 based on the one or more criteria 218. Details about selecting the vehicle configuration 216A are provided, in FIG. 3, and its corresponding description.

With reference to FIG. 6B, the computer system 202 controls the first vehicle 604 and the second vehicle 606 based on the vehicle configuration 216A. The computer system 202 rearranges the first vehicle 604 and the second vehicle 606 to improve the power consumed by the spatial mapping sensor of the first vehicle 604 and the spatial mapping sensor of the second vehicle 606. The power consumption is improved as a common area 612 captured by the spatial mapping sensor of the first vehicle 604 and the spatial mapping sensor of the second vehicle 606 is similar, so the power consumed by the spatial mapping sensor of the first vehicle 604 and the spatial mapping sensor of the second vehicle 606 decreases as the common area 612 captured by the spatial mapping sensor of the first vehicle 604 and the spatial mapping sensor of the second vehicle 606 is utilized by both the first vehicle 604 and the second vehicle 606 rather than the spatial mapping sensor of the first vehicle 604 and the spatial mapping sensor of the second vehicle 606 capturing the common area 612 independently. The reduction in the power consumption by the spatial mapping sensor of the first vehicle 604 and the spatial mapping sensor of the second vehicle 606 further improves the overall range of the first vehicle 604 and the second vehicle 606.

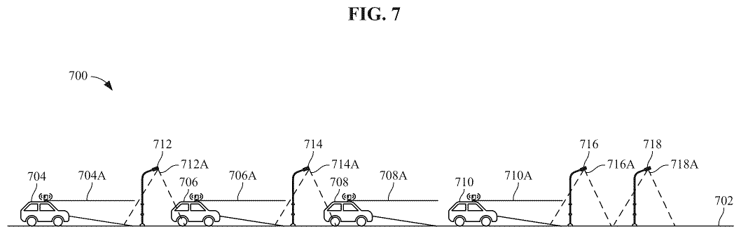

FIG. 7 is a diagram that illustrates an exemplary scenario for generation of a map based on geographical area, in accordance with an embodiment of the disclosure. FIG. 7 is explained in conjunction with elements from FIG. 1, FIG. 2, FIG. 3, FIG. 4, FIG. 5, FIG. 6A, and FIG. 6B. With reference to FIG. 7, there is shown an exemplary diagram 700 that includes a road segment 702, a first vehicle 704, a second vehicle 706, a third vehicle 708, a fourth vehicle 710, a first roadside infrastructure 712, a second roadside infrastructure 714, a third roadside infrastructure 716, and a fourth roadside infrastructure 718. The exemplary diagram 700 further includes a first vehicle geographical area 704A captured by the first vehicle 704, a second vehicle geographical area 706A captured by the second vehicle 706, a third vehicle geographical area 708A captured by the third vehicle 708, a fourth vehicle geographical area 710A captured by the fourth vehicle 710, a first infrastructure geographical area 712A captured by the first roadside infrastructure 712, a second infrastructure geographical area 714A captured by the second roadside infrastructure 714, a third infrastructure geographical area 716A captured by the third roadside infrastructure 716, and a fourth infrastructure geographical area 718A captured by the fourth roadside infrastructure 718. The road segment 702 is an exemplary embodiment of the road segment 210 of FIG. 2. The first vehicle 704 is an exemplary embodiment of the first vehicle 206A of FIG. 2. The second vehicle 706 is an exemplary embodiment of the second vehicle 206B of FIG. 2.

The computer system 202 receives geographical data including first vehicle geographical area 704A that is captured by the spatial mapping sensor of the first vehicle 704, the second vehicle geographical area 706A that is captured by the second mapping sensor of the second vehicle 706, the third vehicle geographical area 708A that is captured by the spatial mapping sensor of the third vehicle 708, the fourth vehicle geographical area 710A that is captured by the spatial mapping sensor of the fourth vehicle 710, the first infrastructure geographical area 712A that is captured by the spatial mapping sensor of the first roadside infrastructure 712, the second infrastructure geographical area 714A that is captured by the spatial mapping sensor of the second roadside infrastructure 714, the third infrastructure geographical area 716A that is captured by the spatial mapping sensor of the third roadside infrastructure 716, and the fourth infrastructure geographical area 718A that is captured by the spatial mapping sensor of the fourth roadside infrastructure 718.

The computer system 202 receives the vehicle data 204A including at least the geographical coordinates of the first vehicle 704, geographical coordinates of the second vehicle 706, geographical coordinates of the third vehicle 708, geographical coordinates of the fourth vehicle 710, the speed of the first vehicle 704, a speed of the second vehicle 706, a speed of the third vehicle 708, a speed of the fourth vehicle 710, traffic congestion status on the road segment 702, heading direction of the first vehicle 704, heading direction of the second vehicle 706, heading direction of the third vehicle 708, and heading direction of the fourth vehicle 710.

The computer system 202 receives the infrastructure connectivity data 204B including at least the traffic signal status on the road segment 702, road surface condition information of the road segment 702, and weather conditions associated with the road segment 702. Further, the computer system 202 receives the map data 204C including at least spatial information of the road segment 702. The spatial information is associated with a specific location or geographic area of the road segment 702.

The computer system 202 further generates a map (e.g., the map 508A) based on the received vehicle data 204A, the received infrastructure connectivity data 204B, the received map data 204C, and the received geographical data. The map is a three-dimensional representation of a geographic area (e.g., the road segment 702) that provides a volumetric visualization of spatial features. The spatial features refer to characteristics of a geographic area that can be represented and analyzed in a spatial context that includes both natural components and human-made components. Natural components include topography (e.g., mountains, valleys), water bodies (e.g., rivers, lakes), and vegetation (e.g., forests, grasslands). Human-made features include infrastructure (e.g., roads, bridges), buildings (e.g., residential, commercial), and land use designations (e.g., agricultural, industrial). By way of example, and not by limitation, the computer system 202 utilizes a geographic information system (GIS) to generate the map by utilizing the received vehicle data 204A, the received infrastructure connectivity data 204B, the received map data 204C, and the received geographical data. The GIS is a framework that enables the collection, storage, analysis, and visualization of spatial information and geographical data (e.g., the geographical data) to generate 3D maps.

The generation of the map by utilizing the geographical data improves the power consumption by the spatial mapping sensor of the first vehicle 704, the spatial mapping sensor of the second vehicle 706, the spatial mapping sensor of the third vehicle 708, and the spatial mapping sensor of the fourth vehicle 710. Further improving the range of at least one of the first vehicle 704, the second vehicle 706, the third vehicle 708, or the fourth vehicle 710.

Further, the computer system 202 transmits the generated map (e.g., the map 508A) to at least the first vehicle 704, the second vehicle 706, the third vehicle 708, and the fourth vehicle 710. In various embodiments of the disclosure, the computer system 202 controls the first vehicle 704 based on the generated map (e.g., the map 508A). In various embodiments of the disclosure, the computer system 202 controls the second vehicle 706 based on the generated map. In various embodiments of the disclosure, the computer system 202 controls the third vehicle 708 based on the generated map. In various embodiments of the disclosure, the computer system 202 controls the fourth vehicle 710 based on the generated map.

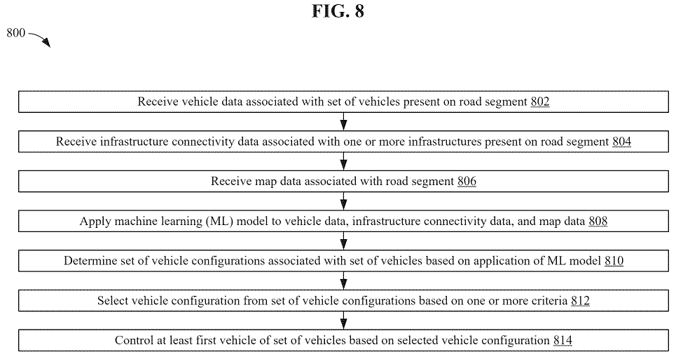

FIG. 8 is a diagram that illustrates a flowchart of a first exemplary method for vehicle configuration determination for vehicle navigation, in accordance with an embodiment of the disclosure. FIG. 8 is explained in conjunction with elements from FIG. 1, FIG. 2, FIG. 3, FIG. 4, FIG. 5, FIG. 6A, FIG. 6B, and FIG. 7. With reference to FIG. 8, there is shown a flowchart 800. The operations of the exemplary method may be executed by any computing system, for example, by the computer 102 of FIG. 1 or the computer system 202 of FIG. 2. The operations of the flowchart 800 may start at 802.

At 802, the vehicle data 204A associated with the set of vehicles 206 present on the road segment 210 is received. The vehicle data 204A includes at least the speed of each vehicle of the set of vehicles 206 and the geographical location of each vehicle of the set of vehicles 206. In an embodiment of the disclosure, the computer system 202 receives the vehicle data 204A associated with the set of vehicles 206 present on the road segment 210. The vehicle data 204A includes at least the speed of each vehicle of the set of vehicles 206 and the geographical location of each vehicle of the set of vehicles 206. Details about receiving the vehicle data 204A are provided, in FIG. 3, and its corresponding description.

At 804, the infrastructure connectivity data 204B associated with the one or more infrastructures 212 present on the road segment 210 is received. The infrastructure connectivity data 204B includes at least the geographical location of each infrastructure of the one or more infrastructures 212. Each infrastructure of the one or more infrastructures 212 includes a first spatial mapping sensor. In an embodiment of the disclosure, the computer system 202 receives the infrastructure connectivity data 204B associated with the one or more infrastructures 212 present on the road segment 210. The infrastructure connectivity data 204B includes at least the geographical location of each infrastructure of the one or more infrastructures 212. Each infrastructure of the one or more infrastructures 212 includes the first spatial mapping sensor. Details about receiving the infrastructure connectivity data 204B are provided, in FIG. 3, and its corresponding description.

At 806, the map data 204C associated with the road segment 210 is received. In an embodiment of the disclosure, the computer system 202 receives the map data 204C associated with the road segment 210. Details about receiving the map data 204C are provided, in FIG. 3, and its corresponding description.

At 808, the ML model 214 is applied to the vehicle data 204A, the infrastructure connectivity data 204B, and the map data 204C. In an embodiment of the disclosure, the computer system 202 applies the ML model 214 to the vehicle data 204A, the infrastructure connectivity data 204B, and the map data 204C. Details about applying the ML model 214 to the vehicle data 204A, the infrastructure connectivity data 204B, and the map data 204C are provided, in FIG. 3, and its corresponding description.

At 810, the set of vehicle configurations 216 associated with the set of vehicles 206 is determined based on the application of the ML model 214. Each vehicle configuration of the set of vehicle configurations 216 indicates the arrangement of the set of vehicles 206 on the road segment 210. In an embodiment of the disclosure, the computer system 202 determines the set of vehicle configurations 216 associated with the set of vehicles 206 based on the application of the ML model 214. Each vehicle configuration of the set of vehicle configurations 216 indicates the arrangement of the set of vehicles 206 on the road segment 210. Details about determining the set of vehicle configurations 216 based on the application of the ML model 214 are provided, in FIG. 3, and its corresponding description.

At 812, the vehicle configuration 216A is selected from the set of vehicle configurations 216 based on the one or more criteria 218. The one or more criteria 218 include at least one of the power consumption by the second spatial mapping sensor of each vehicle of the set of vehicles 206, the driving range of each vehicle of the set of vehicles 206, or the travel route of each vehicle of the set of vehicles 206. In an embodiment of the disclosure, the computer system 202 selects the vehicle configuration 216A from the set of vehicle configurations 216 based on the one or more criteria 218. The one or more criteria 218 include at least one of the power consumption by a second spatial mapping sensor of each vehicle of the set of vehicles 206, the driving range of each vehicle of the set of vehicles 206, or the travel route of each vehicle of the set of vehicles 206. Details about selecting the vehicle configuration 216A based on the one or more criteria 218 are provided, in FIG. 3, and its corresponding description.

At 814, at least the first vehicle 206A of the set of vehicles 206 is controlled based on the vehicle configuration 216A. In an embodiment of the disclosure, the computer system 202 controls at least the first vehicle 206A of the set of vehicles 206 based on the vehicle configuration 216A. Details about controlling at least the first vehicle 206A of the set of vehicles 206 based on the vehicle configuration 216A are provided, in FIG. 3, and its corresponding description.

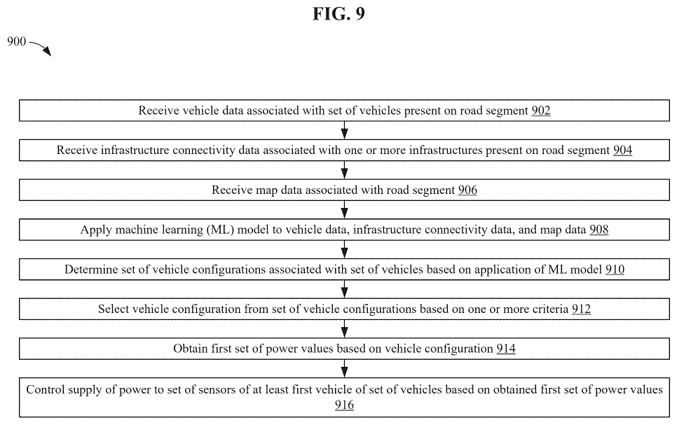

FIG. 9 is a diagram that illustrates a flowchart of a second exemplary method for vehicle configuration determination for vehicle navigation, in accordance with an embodiment of the disclosure. FIG. 9 is explained in conjunction with elements from FIG. 1, FIG. 2, FIG. 3, FIG. 4, FIG. 5, FIG. 6A, FIG. 6B, FIG. 7, and FIG. 8. With reference to FIG. 9, there is shown a flowchart 900. The operations of the exemplary method may be executed by any computing system, for example, by the computer 102 of FIG. 1 or the computer system 202 of FIG. 2. The operations of the flowchart 900 may start at 902.

At 902, the vehicle data 204A associated with the set of vehicles 206 present on the road segment 210 is received. The vehicle data 204A includes at least the speed of each vehicle of the set of vehicles 206 and the geographical location of each vehicle of the set of vehicles 206. In an embodiment of the disclosure, the computer system 202 receives the vehicle data 204A associated with the set of vehicles 206 present on the road segment 210. The vehicle data 204A includes at least the speed of each vehicle of the set of vehicles 206 and the geographical location of each vehicle of the set of vehicles 206. Details about receiving the vehicle data 204A are provided, in FIG. 3, and its corresponding description.

At 904, the infrastructure connectivity data 204B associated with the one or more infrastructures 212 present on the road segment 210 is received. The infrastructure connectivity data 204B includes at least the geographical location of each infrastructure of the one or more infrastructures 212. Each infrastructure of the one or more infrastructures 212 includes the first spatial mapping sensor. In an embodiment of the disclosure, the computer system 202 receives the infrastructure connectivity data 204B associated with the one or more infrastructures 212 present on the road segment 210. The infrastructure connectivity data 204B includes at least the geographical location of each infrastructure of the one or more infrastructures 212. Each infrastructure of the one or more infrastructures 212 includes the first spatial mapping sensor. Details about receiving the infrastructure connectivity data 204B are provided, in FIG. 3, and its corresponding description.

At 906, the map data 204C associated with the road segment 210 is received. In an embodiment of the disclosure, the computer system 202 receives the map data 204C associated with the road segment 210. Details about receiving the map data 204C are provided, in FIG. 3, and its corresponding description.

At 908, the ML model 214 is applied to the vehicle data 204A, the infrastructure connectivity data 204B, and the map data 204C. In an embodiment of the disclosure, the computer system 202 applied the ML model 214 to the vehicle data 204A, the infrastructure connectivity data 204B, and the map data 204C. Details about applying the ML model 214 to the vehicle data 204A, the infrastructure connectivity data 204B, and the map data 204C are provided, in FIG. 3, and its corresponding description.

At 910, the set of vehicle configurations 216 associated with the set of vehicles 206 is determined based on the application of the ML model 214. Each vehicle configuration of the set of vehicle configurations 216 indicates the arrangement of the set of vehicles 206 on the road segment 210. In an embodiment of the disclosure, the computer system 202 determines the set of vehicle configurations 216 associated with the set of vehicles 206 based on the application of the ML model 214. Each vehicle configuration of the set of vehicle configurations 216 indicates the arrangement of the set of vehicles 206 on the road segment 210. Details about determining the set of vehicle configurations 216 based on the application of the ML model 214 are provided, in FIG. 3, and its corresponding description.

At 912, the vehicle configuration 216A is selected from the set of vehicle configurations 216 based on the one or more criteria 218. The one or more criteria 218 include at least one of the power consumption by the second spatial mapping sensor of each vehicle of the set of vehicles 206, the driving range of each vehicle of the set of vehicles 206, or the travel route of each vehicle of the set of vehicles 206. In an embodiment of the disclosure, the computer system 202 selects the vehicle configuration 216A from the set of vehicle configurations 216 based on the one or more criteria 218. The one or more criteria 218 include at least one of the power consumption by the second spatial mapping sensor of each vehicle of the set of vehicles 206, the driving range of each vehicle of the set of vehicles 206, or the travel route of each vehicle of the set of vehicles 206. Details about selecting the vehicle configuration 216A based on the one or more criteria 218 are provided, in FIG. 3, and its corresponding description.

At 914, the first set of power values is obtained based on the vehicle configuration 216A. In an embodiment of the disclosure, the computer system 202 obtains the first set of power values based on the vehicle configuration 216A. Details about obtaining the first set of power values based on the vehicle configuration 216A are provided, in FIG. 3, and its corresponding description.

At 916, the supply of power to the set of sensors of at least the first vehicle 206A of the set of vehicles 206 is controlled based on the obtained first set of power values. The set of sensors of at least the first vehicle 206A includes the second spatial mapping sensor. In an embodiment of the disclosure, the computer system 202 controls the supply of power to the set of sensors of at least the first vehicle 206A of the set of vehicles 206 based on the obtained first set of power values. The set of sensors of at least the first vehicle 206A includes the second spatial mapping sensor. Details about controlling the supply of power to the set of sensors of at least the first vehicle 206A of the set of vehicles 206 based on the obtained first set of power values are provided, in FIG. 3, and its corresponding description.

The scope of the disclosure is not limited to the descriptions of the various embodiments of the disclosure that have been presented. Modifications apparent to those of ordinary skill in the art without departing from the scope and spirit of the described embodiments may implement the idea described in the disclosure to, for example, autonomous robots. The autonomous robots may perform operations in various areas of implementation, by way of example, but not limited to, construction areas, and rescue sites to rescue people.

The descriptions of the various embodiments of the disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable people of ordinary skill in the art to understand the embodiments disclosed herein.

What is claimed is:

1. A computer-implemented method, comprising:
receiving, by a computer, vehicle data associated with a set of vehicles present on a road segment, wherein the vehicle data comprises a speed of each vehicle of the set of vehicles, and a geographical location of each vehicle of the set of vehicles;
receiving, by the computer, infrastructure connectivity data associated with one or more infrastructures present on the road segment, wherein the infrastructure connectivity data comprises a geographical location of each infrastructure of the one or more infrastructures, and wherein each infrastructure of the one or more infrastructures comprises a first spatial mapping sensor;
receiving, by the computer, map data associated with the road segment;
applying, by the computer, a machine learning (ML) model to the vehicle data, the infrastructure connectivity data, and the map data;
determining, by the computer, a set of vehicle configurations associated with the set of vehicles based on an application of the ML model, wherein each vehicle configuration of the set of vehicle configurations indicates an arrangement of the set of vehicles on the road segment;
selecting, by the computer, a vehicle configuration from the set of vehicle configurations based on one or more criteria, wherein the one or more criteria comprise one of a power consumption by a second spatial mapping sensor of each vehicle of the set of vehicles, a driving range of each vehicle of the set of vehicles, or a travel route of each vehicle of the set of vehicles; and
controlling, by the computer, at least a first vehicle of the set of vehicles based on the selected vehicle configuration.

2. The computer-implemented method of claim 1, further comprising:
obtaining, by the computer, a first set of power values based on the selected vehicle configuration; and
controlling, by the computer, a supply of power to a set of sensors of at least the first vehicle of the set of vehicles based on the obtained first set of power values, wherein the set of sensors of at least the first vehicle comprises the second spatial mapping sensor.

3. The computer-implemented method of claim 2, further comprising:
obtaining, by the computer, a second set of power values associated with the selected vehicle configuration;
transmitting, by the computer, the second set of power values to a set of sensors associated with at least one infrastructure of the one or more infrastructures, wherein the set of sensors associated with the at least one infrastructure comprises the first spatial mapping sensor; and
controlling, by the computer, a supply of power to the set of sensors of the at least one infrastructure based on the transmission of the second set of power values.

4. The computer-implemented method of claim 1, further comprising:
generating, by the computer, a virtual representation of the set of vehicle configurations associated with the set of vehicles present on the road segment, wherein the virtual representation is generated based on the application of the ML model to the vehicle data, the infrastructure connectivity data, and the map data;
simulating, by the computer, the virtual representation of the set of vehicle configurations based on the one or more criteria; and
selecting, by the computer, the vehicle configuration based on a result of the simulation and the one or more criteria.

5. The computer-implemented method of claim 1, further comprising:
controlling, by the computer, a set of sensors of the first vehicle to capture a first geographical area, wherein the set of sensors of the first vehicle comprises the second spatial mapping sensor;
controlling, by the computer, at least one of a set of sensors of a second vehicle of the set of vehicles or a set of sensors of at least one infrastructure of the one or more infrastructures to capture a second geographical area, wherein the set of sensors of the second vehicle comprises the second spatial mapping sensor, and wherein the set of sensors of the at least one infrastructure of the one or more infrastructures comprise the first spatial mapping sensor;
determining, by the computer, a third geographical area based on the first geographical area and the second geographical area, wherein the third geographical area corresponds to a union of the first geographical area and the second geographical area;
generating, by the computer, a map associated with the road segment based on the third geographical area, the infrastructure connectivity data, and the map data, wherein the map indicates a visual representation of the third geographical area;
transmitting, by the computer, the generated map to at least the first vehicle; and
controlling, by the computer, a navigation of the first vehicle through the road segment based on the transmission of the generated map.

6. The computer-implemented method of claim 1, further comprising:
obtaining, by the computer, atmospheric data associated with an environment of the road segment based on the selected vehicle configuration;
applying, by the computer, the ML model to the obtained atmospheric data;
determining, by the computer, a set of vehicle illuminance values based on the application of the ML model to the atmospheric data; and
controlling, by the computer, an intensity of light emitted by at least one light emitting device associated with at least the first vehicle, wherein the intensity of light emitted by the at least one light emitting device associated with at least the first vehicle is controlled based on the determined set of vehicle illuminance values.

7. The computer-implemented method of claim 6, further comprising:
determining, by the computer, a set of infrastructure illuminance values based on the application of the ML model to the atmospheric data; and
controlling, by the computer, an intensity of light emitted by one or more light emitting devices associated with at least one infrastructure of the one or more infrastructures, wherein the intensity of light emitted by the one or more light emitting devices associated with the at least one infrastructure is controlled based on the determined set of infrastructure illuminance values, and wherein the one or more light devices illuminate at least the road segment.

8. The computer-implemented method of claim 1, wherein the map data comprises one of a geographical location of one or more traffic signals present on the road segment, a status of each traffic signal of the one or more traffic signals, a surface quality of the road segment, a status of traffic present on the road segment, a maximum allowable speed limit for the road segment, a width of the road segment, a set of lanes within the road segment, a width of each lane of the set of lanes, or a presence of a physical divider within the road segment.

9. A computer system, comprising:
a processor set;
one or more computer-readable storage media; and
program instructions stored on the one or more computer-readable storage media, the program instructions executable by the processor set to cause the processor set to:
receive vehicle data associated with a set of vehicles present on a road segment, wherein the vehicle data comprises a speed of each vehicle of the set of vehicles, and a geographical location of each vehicle of the set of vehicles;
receive infrastructure connectivity data associated with one or more infrastructures present on the road segment, wherein the infrastructure connectivity data comprises a geographical location of each infrastructure of the one or more infrastructures, and wherein each infrastructure of the one or more infrastructures comprises a first spatial mapping sensor;
receive map data associated with the road segment;
apply a machine learning (ML) model to the vehicle data, the infrastructure connectivity data, and the map data;
determine a set of vehicle configurations associated with the set of vehicles based on an application of the ML model, wherein each vehicle configuration of the set of vehicle configurations indicates an arrangement of the set of vehicles on the road segment;
select a vehicle configuration from the set of vehicle configurations based on one or more criteria, wherein the one or more criteria comprise one of power consumption by a second spatial mapping sensor of each vehicle of the set of vehicles, a driving range of each vehicle of the set of vehicles, or a travel route of each vehicle of the set of vehicles;
obtain a first set of power values based on the selected vehicle configuration; and
control a supply of power to a set of sensors of at least a first vehicle of the set of vehicles based on the obtained first set of power values, wherein the set of sensors of at least the first vehicle comprises the second spatial mapping sensor.

10. The computer system of claim 9, wherein the program instructions further cause the processor set to:
obtain a second set of power values associated with the selected vehicle configuration;
transmit the second set of power values to a set of sensors associated with at least one infrastructure of the one or more infrastructures, wherein the set of sensors associated with the at least one infrastructure comprises the first spatial mapping sensor; and
control a supply of power to the set of sensors of the at least one infrastructure based on the transmission of the second set of power values.

11. The computer system of claim 9, wherein the program instructions further cause the processor set to:
generate a virtual representation of the set of vehicle configurations associated with the set of vehicles present on the road segment, wherein the virtual representation is generated based on the application of the ML model to the vehicle data, the infrastructure connectivity data, and the map data;
simulate the virtual representation of the set of vehicle configurations based on the one or more criteria; and
select the vehicle configuration based on a result of the simulation and the one or more criteria.

12. The computer system of claim 9, wherein the program instructions further cause the processor set to:
control the set of sensors of the first vehicle to capture a first geographical area, wherein the set of sensors of the first vehicle comprises the second spatial mapping sensor;
control at least one of a set of sensors of a second vehicle of the set of vehicles or a set of sensors of at least one infrastructure of the one or more infrastructures to capture a second geographical area, wherein the set of sensors of the second vehicle comprises the second spatial mapping sensor, and wherein the set of sensors of the at least one infrastructure of the one or more infrastructures comprise the first spatial mapping sensor;
determine a third geographical area based on the first geographical area and the second geographical area, wherein the third geographical area corresponds to a union of the first geographical area and the second geographical area;
generate a map associated with the road segment based on the third geographical area, the infrastructure connectivity data, and the map data, wherein the map indicates a visual representation of the third geographical area;
transmit the generated map to at least the first vehicle; and
control a navigation of the first vehicle through the road segment based on the transmission of the generated map.

13. The computer system of claim 9, wherein the program instructions further cause the processor set to:
obtain atmospheric data associated with an environment of the road segment based on the selected vehicle configuration;
apply the ML model to the obtained atmospheric data;
determine a set of vehicle illuminance values based on the application of the ML model to the atmospheric data; and
control an intensity of light emitted by at least one light emitting device associated with at least the first vehicle, wherein the intensity of light emitted by the at least one light emitting device associated with at least the first vehicle is controlled based on the determined set of vehicle illuminance values.

14. The computer system of claim 13, wherein the program instructions further cause the processor set to:
determine a set of infrastructure illuminance values based on the application of the ML model to the atmospheric data; and
control an intensity of light emitted by one or more light emitting devices associated with at least one infrastructure of the one or more infrastructures, wherein the intensity of light emitted by the one or more light emitting devices associated with the at least one infrastructure is controlled based on the determined set of infrastructure illuminance values, and wherein the one or more light devices illuminate at least the road segment.

15. The computer system of claim 9, wherein the map data comprises one of a geographical location of one or more traffic signals present on the road segment, a status of each traffic signal of the one or more traffic signals, a surface quality of the road segment, a status of traffic present on the road segment, a maximum allowable speed limit for the road segment, a width of the road segment, a set of lanes within the road segment, a width of each lane of the set of lanes, or a presence of a physical divider within the road segment.

16. A computer program product to control at least one vehicle, the computer program product comprising:
one or more computer-readable storage media; and
program instructions stored on the one or more computer-readable storage media to perform operations comprising:
receiving vehicle data associated with a set of vehicles present on a road segment, wherein the vehicle data comprises a speed of each vehicle of the set of vehicles, and a geographical location of each vehicle of the set of vehicles;
receiving infrastructure connectivity data associated with one or more infrastructures present on the road segment, wherein the infrastructure connectivity data comprises a geographical location of each infrastructure of the one or more infrastructures, and wherein each infrastructure of the one or more infrastructures comprises a first spatial mapping sensor;
receiving map data associated with the road segment;
applying a machine learning (ML) model to the vehicle data, the infrastructure connectivity data, and the map data;
determining a set of vehicle configurations associated with the set of vehicles based on an application of the ML model, wherein each vehicle configuration of the set of vehicle configurations indicates an arrangement of the set of vehicles on the road segment;
selecting a vehicle configuration from the set of vehicle configurations based on one or more criteria, wherein the one or more criteria comprise one of power consumption by a second spatial mapping sensor of each vehicle of the set of vehicles, a driving range of each vehicle of the set of vehicles, or a travel route of each vehicle of the set of vehicles; and
controlling the at least one vehicle of the set of vehicles based on the selected vehicle configuration.

17. The computer program product of claim 16, wherein the operations further comprise:
obtaining a first set of power values associated with the selected vehicle configuration; and
controlling a supply of power to a set of sensors of at least a first vehicle of the set of vehicles based on the obtained first set of power values, wherein the set of sensors of at least the first vehicle comprises the second spatial mapping sensor.

18. The computer program product of claim 17, wherein the operations further comprise:
obtaining a second set of power values associated with the selected vehicle configuration;
transmitting the second set of power values to a set of sensors associated with at least one infrastructure of the one or more infrastructures, wherein the set of sensors associated with the at least one infrastructure comprises the first spatial mapping sensor; and
controlling a supply of power to the set of sensors of the at least one infrastructure based on the transmission of the second set of power values.

19. The computer program product of claim 16, wherein the operations further comprise:
generating a virtual representation of the set of vehicle configurations associated with the set of vehicles present on the road segment, wherein the virtual representation is generated based on the application of the ML model to the vehicle data, the infrastructure connectivity data, and the map data;
simulating the virtual representation of the set of vehicle configurations based on the one or more criteria; and
selecting the vehicle configuration based on a result of the simulation and the one or more criteria.

20. The computer program product of claim 16, wherein the map data comprises one of a geographical location of one or more traffic signals present on the road segment, a status of each traffic signal of the one or more traffic signals, a surface quality of the road segment, a status of traffic present on the road segment, a maximum allowable speed limit for the road segment, a width of the road segment, a set of lanes within the road segment, a width of each lane of the set of lanes, or a presence of a physical divider within the road segment.
